(19) United States
(12) Patent Application Publication
(10) Pub. No.: US 2018/0182968 A1
(43) Pub. Date: Jun. 28, 2018

(54) POLYMER COMPOUND, COMPOSITION INCLUDING THE POLYMER COMPOUND, AND ORGANIC LIGHT-EMITTING DEVICE INCLUDING THE POLYMER COMPOUND

(71) Applicant: Samsung Electronics Co., Ltd., Suwon-si (KR)

(72) Inventors: Katsunori SHIBATA, Yokohama-city (JP); Fumiaki KATO, Yokohama-city (JP); Yusaku KONISHI, Yokohama-city (JP); Fujiyama TAKAHIRO, Yokohama-city (JP)

(21) Appl. No.: 15/855,135

(22) Filed: Dec. 27, 2017

(30) Foreign Application Priority Data
Dec. 27, 2016 (JP) 2016-253645
Dec. 1, 2017 (KR) 10-2017-0164324

(51) Int. Cl. H01L 51/00; C08G 61/12

(52) U.S. Cl. CPC H01L 51/0039; H01L 51/5056; H01L 51/0043; C08G 61/124

(57) ABSTRACT

A polymer compound including a first repeating unit represented by Formula 1 and a second repeating unit represented by Formula 3:

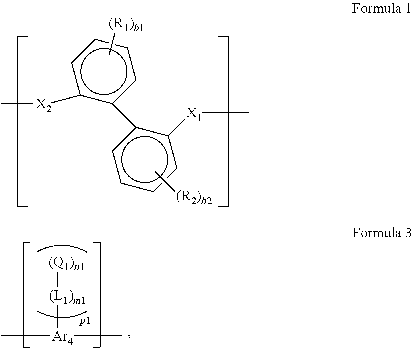

wherein in Formulae 1 and 3, groups and variables are the same as described in the specification.

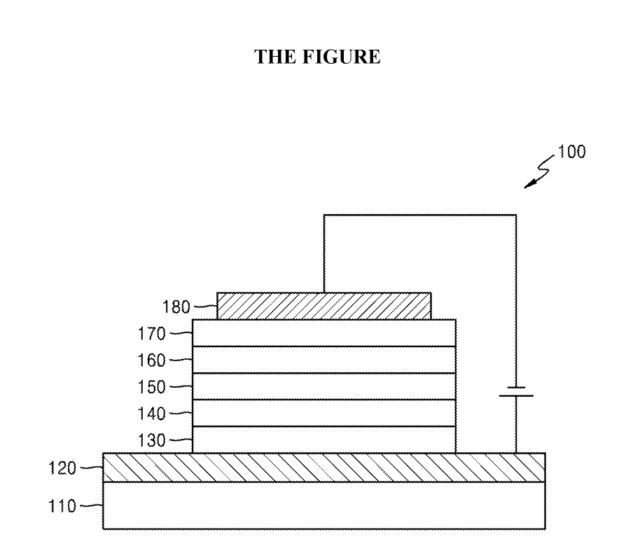

### CROSS-REFERENCE TO RELATED APPLICATIONS

This application claims priority to Japanese Patent Application No. 2016-253645, filed on Dec. 27, 2016, in the Japanese Patent Office, and Korean Patent Application No. 10-2017-0164324, filed on Dec. 1, 2017, in the Korean Intellectual Property Office, and all the benefits accruing therefrom under 35 U.S.C. § 119, the contents of which are incorporated herein in their entireties by reference.

### BACKGROUND

### 1. Field

One or more embodiments relate to a polymer compound, a composition including the polymer compound, and a method of manufacturing an organic light-emitting device.

### 2. Description of the Related Art

Recently, display devices, mobile devices, lighting devices, and the like, using organic light-emitting devices that are self-emission devices, have been actively developed.

As materials of the organic light-emitting devices, a variety of low-molecular-weight materials and high-molecular-weight materials are used for an emission layer and a charge transport layer. In particular, many low-molecular-weight materials that are excellent in terms of device efficiency and lifespan have been proposed, and commercialization thereof has begun in mobile applications. However, the biggest problem with organic light-emitting devices including low-molecular-weight materials is manufacturing costs. In order to solve this problem, there is a need to develop a coating material such as a polymer material.

### SUMMARY

As a polymer material capable of forming a film by solution coating, an arylamine polymer for a hole transport material has been proposed.

Also, organic light-emitting devices using phosphorescent materials exhibiting high luminescent efficiency, such as a 2-phenylpyridine iridium complex [Ir(ppy)₃], have been actively developed. In addition to such light-emitting materials, carrier transport materials may preferably have a high triplet energy level (for example, 2.5 electron volts (eV) or higher). However, in the case of the arylamine polymer, a repeating unit itself has a sufficiently high triplet energy level, but the triplet energy level is reduced as the number of repeating units increase. Therefore, research has been conducted into polymer materials enabling a film or a layer to be formed in a large area having increased luminescent efficiency.

Additional aspects will be set forth in part in the description which follows and, in part, will be apparent from the description, or may be learned by practice of the presented embodiments.

An aspect of the present disclosure provides a polymer material including:

a first repeating unit represented by Formula 1; and

a second repeating unit represented by Formula 3:

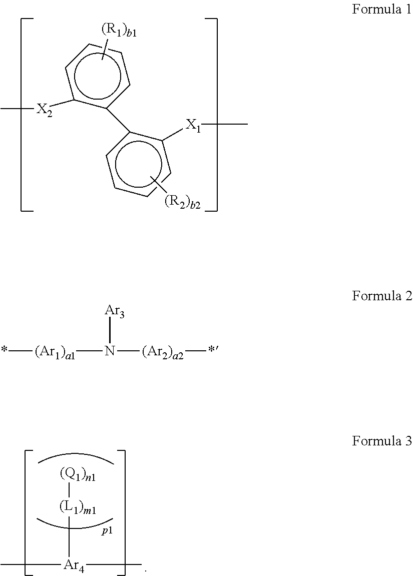

In Formula 1,

X₁ and X₂ may each independently be represented by Formula 2,

R₁ and R₂ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,

b1 and b2 may each independently be an integer from 1 to 4,

when b1 is two or more, two or more groups R₁ may be identical to or different from each other, and

when b2 is two or more, two or more groups R₂ may be identical to or different from each other,

wherein in Formula 2,

An to Ar₃ may each independently be selected from a substituted or unsubstituted C₅-C₃₀ carbocyclic group and a substituted or unsubstituted C₁-C₃₀ heterocyclic group,

a1 and a2 may each independently be an integer from 0 to 4,

provided that, when a1 is zero, Ar₁ is a single bond, and

when a2 is zero, Ar₂ is a single bond, and

* and *′ each indicate a binding site to a neighboring atom,

wherein in Formula 3,

Ar₄ may be a substituted or unsubstituted C₅-C₃₀ carbocyclic group or a substituted or unsubstituted C₁-C₃₀ heterocyclic group,

L₁ may be a single bond, a substituted or unsubstituted C₁-C₆₀ alkylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

m1 may be an integer from 1 to 5,

when m1 is two or more, two or more groups L₁ may be identical to or different from each other,

Q₁ may be a monovalent crosslinking group including at least one selected from an ether group, a vinyl group, an acrylate group, a methacrylate group, a styryl group, an epoxy group, an oxetane group, and a benzocyclobutene group,

n1 may be an integer from 1 to 5,

when n1 is two or more, two or more groups Q₁ may be identical to or different from each other, and

p1 may be an integer from 1 to 5, wherein, when p1 is two or more, two or more groups -(L₁)ₘ₁-(Q₁)ₙ₁ may be identical to or different from each other.

According to the above aspect, it is possible to provide an organic layer having excellent thermal stability and an organic light-emitting device having an improved emission lifespan.

Another aspect of the present disclosure provides a composition for manufacturing an organic light-emitting device, the composition the polymer compound and a liquid medium.

According to the above aspect, it is possible to provide an organic layer having excellent thermal stability and an organic light-emitting device having an improved emission lifespan, and it is possible to provide a composition suitable for solution coating.

Another aspect of the present disclosure provides an organic light-emitting device including:

a first electrode;

a second electrode; and

an organic layer disposed between the first electrode and the second electrode,

wherein the organic layer includes an emission layer and the polymer compound.

According to the above aspect, it is possible to provide an organic layer having excellent thermal stability and an organic light-emitting device having an improved emission lifespan.

Another aspect of the present disclosure provides a method of manufacturing an organic light-emitting device, the organic light-emitting device including a first electrode, a second electrode, and an organic layer disposed between the first electrode and the second electrode, wherein the organic layer includes an emission layer and the polymer compound, and wherein the method includes forming a layer including the polymer compound by solution coating using a composition including the polymer compound and a liquid medium.

According to the above aspect, it is possible to provide an organic layer having excellent thermal stability and a large-area organic light-emitting device having an improved emission lifespan.

### BRIEF DESCRIPTION OF THE DRAWING

These and/or other aspects will become apparent and more readily appreciated from the following description of the embodiments, taken in conjunction with the FIGURE, which is a schematic view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present disclosure. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Polymer Compound

An aspect of the present disclosure provides a polymer compound including:

a first repeating unit represented by Formula 1; and

a second repeating unit represented by Formula 3:

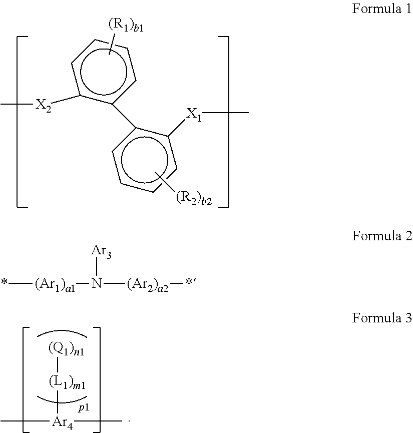

In Formula 1,

X₁ and X₂ may each independently be represented by Formula 2,

R₁ and R₂ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted, or a unsubstituted monovalent non-aromatic condensed heteropolycyclic group,

b1 and b2 may each independently be an integer from 1 to 4,

when b1 is two or more, R₁ may be identical to or different from each other, and

when b2 is two or more, R₂ may be identical to or different from each other,

wherein in Formula 2,

Ar₁ to Ar₃ may each independently be selected from a substituted or unsubstituted C₅-C₃₀ carbocyclic group and a substituted or unsubstituted C₁-C₃₀ heterocyclic group,

a1 and a2 may each independently be an integer from 0 to 4, provided that a1+a2≥1,

when a1 is zero, Ar₁ may be a single bond,

when a2 is zero, Ar₂ may be a single bond, and

* and *′ each indicate a binding site to a neighboring atom,

wherein in Formula 3,

Ar₄ may be a substituted or unsubstituted C₅-C₃₀ carbocyclic group or a substituted or unsubstituted C₁-C₃₀ heterocyclic group,

L₁ may be a single bond, a substituted or unsubstituted C₁-C₆₀ alkylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

m1 may be an integer from 1 to 5,

when m1 is two or more, two or more groups L₁ may be identical to or different from each other,

Q₁ may be a monovalent crosslinking group including at least one selected from an ether group, a vinyl group, an acrylate group, a methacrylate group, a styryl group, an epoxy group, an oxetane group, and a benzocyclobutene group,

n1 may be an integer from 1 to 5,

when n1 is two or more, two or more groups Q₁ may be identical to or different from each other,

p1 may be an integer from 1 to 5, wherein, when p1 is two or more, two or more groups -(L₁)ₘ₁-(Q₁)ₙ₁ may be identical to or different from each other.

First Repeating Unit

The polymer compound includes a first repeating unit represented by Formula 1. For example, the polymer compound may include first repeating units having the same structure, or may include two or more first repeating units having different structures.

X₁ and X₂ in Formula 1 may each independently be represented by Formula 2.

In an embodiment, X₁ and X₂ may be identical to each other.

In one or more embodiments, X₁ and X₂ may be different from each other.

Ar₁ to Ar₂ in Formula 2 may each independently be selected from a substituted or unsubstituted C₅-C₃₀ carbocyclic group and a substituted or unsubstituted C₁-C₃₀ heterocyclic group, and a1 and a2 may each independently be an integer from 0 to 4.

In an embodiment, a1 and a2 may each independently be an integer from 0 to 2.

In an embodiment, a1 and a2 in Formula 2 may satisfy a1+a2≥1. That is, at least one of Ar₁ and Ar₂ in Formula 2 is not a single bond.

In an embodiment, Ar₁ to Ar₃ may each independently be selected from:

a benzene group, a naphthalene group, a fluorene group, a spiro-bifluorene group, an indene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, a quinoline group, an isoquinoline group, a benzoquinoline group, a quinoxaline group, a quinazoline group, a carbazole group, a benzimidazole group, a benzofuran group, a benzothiophene group, an isobenzothiophene group, a benzoxazole group, an isobenzoxazole group, a triazole group, a tetrazole group, an oxadiazole group, a triazine group, a dibenzofuran group, and a dibenzothiophene group; and

a benzene group, a naphthalene group, a fluorene group, a spiro-bifluorene group, an indene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, a quinoline group, an isoquinoline group, a benzoquinoline group, a quinoxaline group, a quinazoline group, a carbazole group, a benzimidazole group, a benzofuran group, a benzothiophene group, an isobenzothiophene group, a benzoxazole group, an isobenzoxazole group, a triazole group, a tetrazole group, an oxadiazole group, a triazine group, a dibenzofuran group, and a dibenzothiophene group, each substituted with at least one selected from deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group.

In one or more embodiments, Ar₁ and Ar₂ may each independently be selected from a phenylene group, a naphthylene group, a fluorenylene group, a spiro-bifluorenylene group, a triphenylenylene group, an indenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, a quinolinylene group, an isoquinolinylene group, a benzoquinolinylene group, a quinoxalinylene group, a quinazolinylene group, a carbazolylene group, a benzimidazolylene group, a benzofuranylene group, a benzothiophenylene group, an iso-benzothiophenylene group, a benzoxazolylene group, an isobenzoxazolylene group, a triazolylene group, a tetrazolylene group, an oxadiazolylene group, a triazinylene group, a dibenzofuranylene group, and a dibenzothiophenylene group; and

a phenylene group, a naphthylene group, a fluorenylene group, a spiro-bifluorenylene group, a triphenylenylene group, an indenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, a quinolinylene group, an isoquinolinylene group, a benzoquinolinylene group, a quinoxalinylene group, a quinazolinylene group, a carbazolylene group, a benzimidazolylene group, a benzofuranylene group, a benzothiophenylene group, an iso-benzothiophenylene group, a benzoxazolylene group, an isobenzoxazolylene group, a triazolylene group, a tetrazolylene group, an oxadiazolylene group, a triazinylene group, a dibenzofuranylene group, and a dibenzothiophenylene group, each substituted with at least one selected from deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group.

In one or more embodiments, Ar₂ may be selected from:

a phenyl group, a naphthyl group, a fluorenyl group, a spiro-bifluorenyl group, a triphenylenyl group, an indenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a quinazolinyl group, a carbazolyl group, a benzimidazolyl group, a benzofuranyl group, a benzothiophenyl group, an iso-benzothiophenyl group, a benzoxazolyl group, an isobenzoxazolyl group, a triazolyl group, a tetrazolyl group, an oxadiazolyl group, a triazinyl group, a dibenzofuranyl group, and a dibenzothiophenyl group; and

a phenyl group, a naphthyl group, a fluorenyl group, a spiro-bifluorenyl group, a triphenylenyl group, an indenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a quinazolinyl group, a carbazolyl group, a benzimidazolyl group, a benzofuranyl group, a benzothiophenyl group, an iso-benzothiophenyl group, a benzoxazolyl group, an isobenzoxazolyl group, a triazolyl group, a tetrazolyl group, an oxadiazolyl group, a triazinyl group, a dibenzofuranyl group, and a dibenzothiophenyl group, each substituted with at least one selected from deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group.

For example, Ar₁ to Ar₃ may each independently be selected from:

a benzene group, a carbazole group, a fluorene group, and a triphenylene group; and

a benzene group, a carbazole group, a fluorene group, and a triphenylene group, each substituted with at least one selected from deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a carbazole group, a fluorenyl group, and a triphenylenyl group, but embodiments of the present disclosure are not limited thereto.

For example, Ar₁ and Ar₂ may each independently be selected from:

a phenylene group, a carbazolylene group, a fluorenylene group, and a triphenylenylene group; and

a phenylene group, a carbazolylene group, a fluorenylene group, and a triphenylenylene group, each substituted with at least one selected from deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a carbazole group, a fluorenyl group, and a triphenylenyl group, but embodiments of the present disclosure are not limited thereto.

For example, Ar₃ may be selected from:

a phenyl group, a carbazolyl group, a fluorenyl group, and a triphenylene group; and

a phenyl group, a carbazolyl group, a fluorenyl group, and a triphenylene group, each substituted with at least one selected from deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a carbazole group, a fluorenyl group, and a triphenylenyl group, but embodiments of the present disclosure are not limited thereto.

In an embodiment, Ar₁ and Ar₂ may each independently be a substituent represented by one selected from Formulae A-1 to A-9:

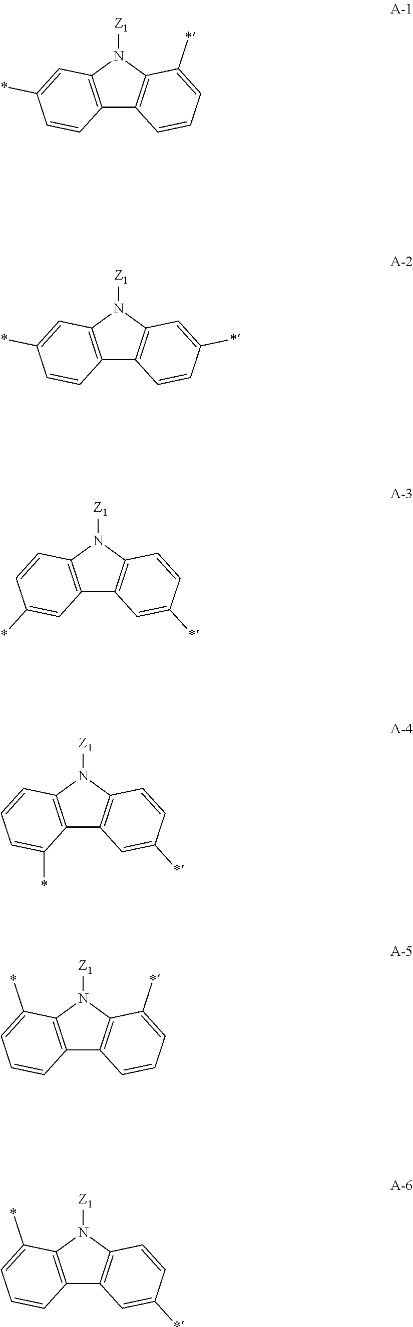

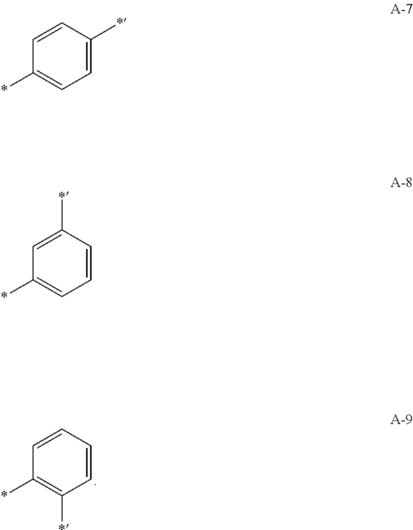

In Formulae A-1 to A-9,

Z₁ may be hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group, and

* and *′ each indicate a binding site to a neighboring atom.

In an embodiment, Z₁ may be selected from:

hydrogen, deuterium, —F, —Cl, —Br, —I, a hydroxyl group, a phenyl group, a naphthyl group, a fluorenyl group, a triphenylenyl group, a spiro-bifluorenyl group, a biphenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group; and

a phenyl group, a naphthyl group, a fluorenyl group, a spiro-bifluorenyl group, a triphenylenyl group, a biphenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-bifluorenyl group, a triphenylenyl group, a biphenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group.

For example, Z₁ may be a phenyl group, a fluorenyl group, a phenyl group substituted with a C₁-C₆₀ alkyl group, or a fluorenyl group substituted with a C₁-C₆₀ alkyl group.

In an embodiment, Ar₁ and Ar₂ may each independently be a substituent represented by Formula A-3 or A-4.

In an embodiment, Ar₁ and Ar₂ may each independently be a substituent represented by one selected from Formulae 5-1 to 5-6, but embodiments of the present disclosure are not limited thereto:

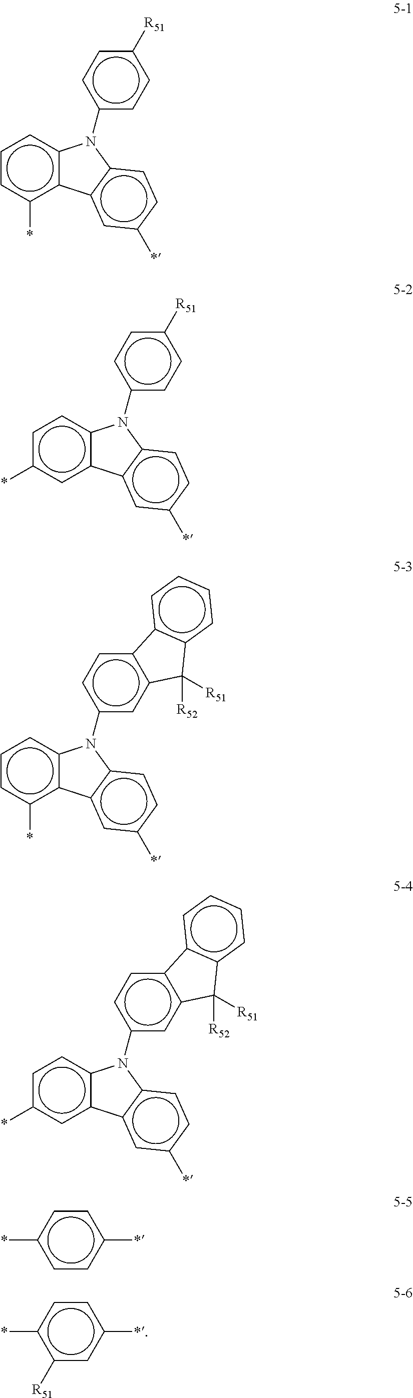

In Formulae 5-1 to 5-6,

R₅₁ and R₅₂ may each independently be hydrogen, deuterium, —F, —Cl, —Br, —I, a hydroxyl group, a cyano group, a nitro group, an amino group, or a C₁-C₆₀ alkyl group, and

* and *′ each indicate a binding site to a neighboring atom.

In Formula 3, b1 and b2 may each independently be an integer form 1 to 4, and when b1 is 2 or greater, a plurality of groups R₁ may be identical to or different from each other, and when b2 is 2 or greater, a plurality of groups R₂ may be identical to or different from each other.

In an embodiment, b1 and b2 may each independently be 1 or 2, but embodiments of the present disclosure are not limited thereto.

In an embodiment, Ar₃ may be a substituent represented by one selected from Formulae B-1 to B-7:

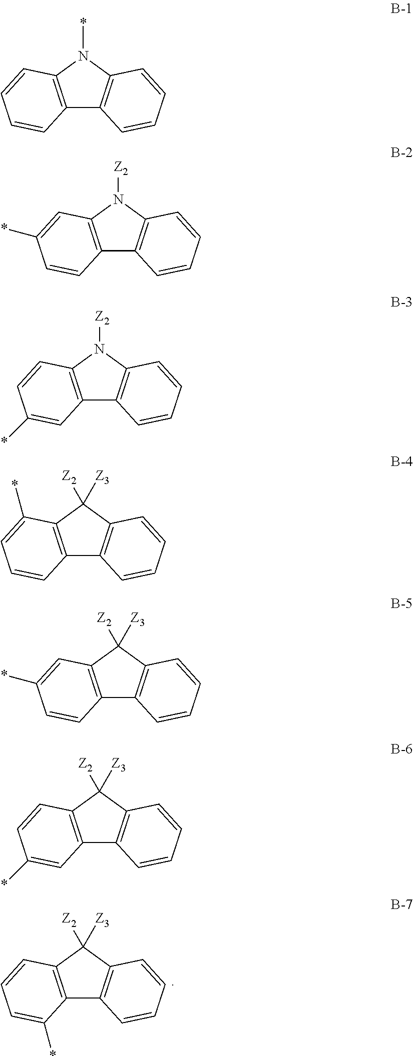

In Formulae B-1 to B-7,

Z₂ and Z₃ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and

* indicates a binding site to a neighboring atom.

In an embodiment, Z₂ and Z₃ may each independently be understood by referring to the description of Z₁ of Formulae A-1 to A-6.

In Formula 1, R₁ and R₂ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

In an embodiment, R₁ and R₂ may each independently be selected from:

hydrogen, deuterium, —F, —CSI, —Br, —I, a hydroxyl group, a C₁-C₂₀ alkyl group, a C₁-C₂₀ alkoxy group, a phenyl group, a naphthyl group, a fluorenyl group, a spiro-bifluorenyl group, a triphenylenyl group, a biphenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group; and

a phenyl group, a naphthyl group, a fluorenyl group, a spiro-bifluorenyl group, a biphenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, a fluorenyl group, a spiro-bifluorenyl group, a triphenylenyl group, a biphenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group.

For example, R₁ and R₂ may each independently be selected from hydrogen, deuterium, —F, —Cl, —Br, —I, a hydroxyl group, a C₁-C₂₀ alkyl group, a C₁-C₂₀ alkoxy group, a phenyl group, a naphthyl group, a fluorenyl group, a spiro-bifluorenyl group, a triphenylenyl group, a biphenyl group, a dimethylfluorenyl group, and a diphenylfluorenyl group, a carbazolyl group, but embodiments of the present disclosure are not limited thereto.

In an embodiment, R₁ and R₂ may each independently be hydrogen.

In Formula 1, b1 and b2 may each independently be an integer from 1 to 4, and when b1 is 2 or greater, a plurality of groups R₁ may be identical to or different from each other, and when b2 is 2 or greater, a plurality of groups R₂ may be identical to or different from each other.

In Formula 1, X₁ and X₂ may each independently be represented by Formula 2, and the first repeating unit represented by Formula 1 may be represented by Formula 10:

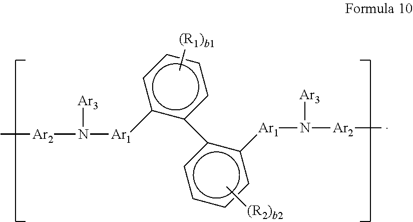

In Formula 10,

R₁, R₂, b1, b2, and Ar₁ to Ar₃ are each independently the same as those defined in Formulae 1 and 2.

In an embodiment, the first repeating unit may be a repeating unit represented by one selected from Formulae 1-1 to 1-10.

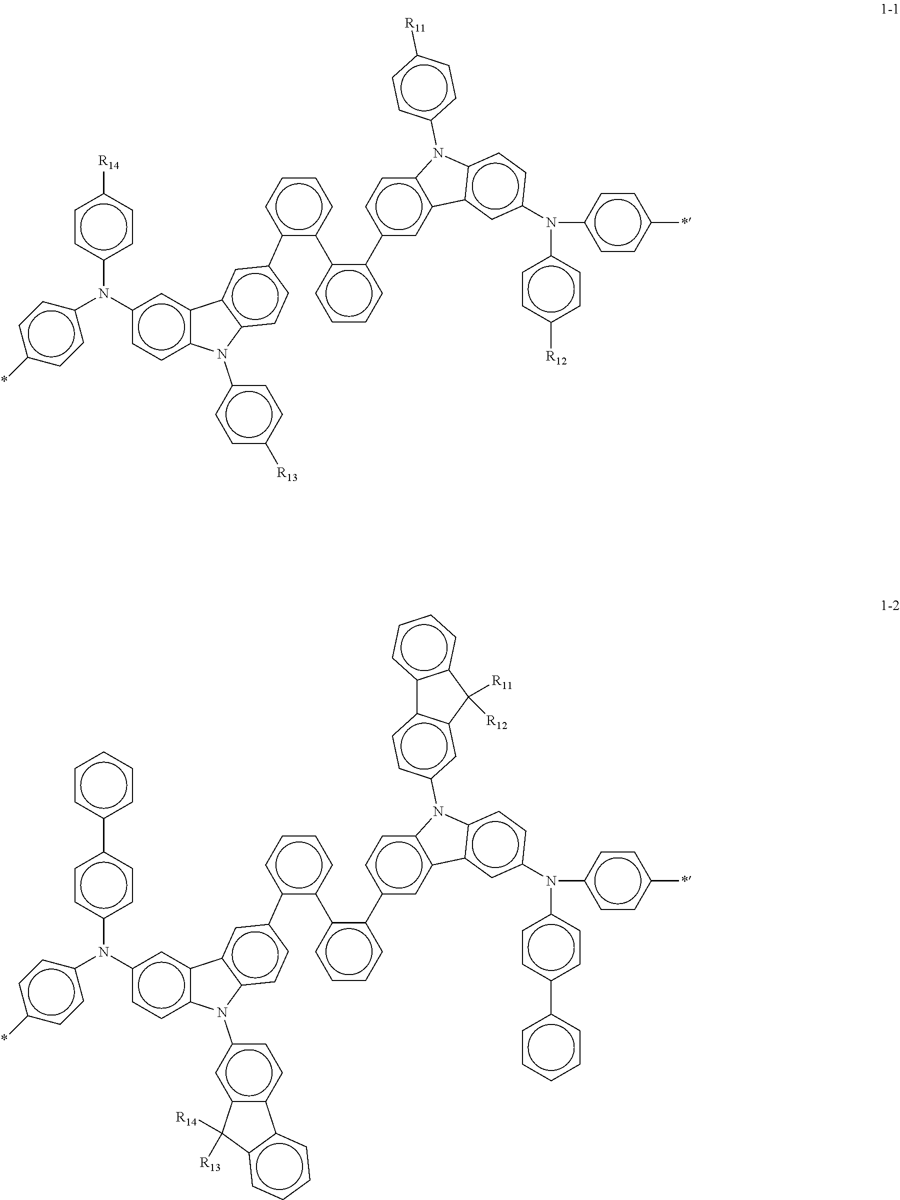

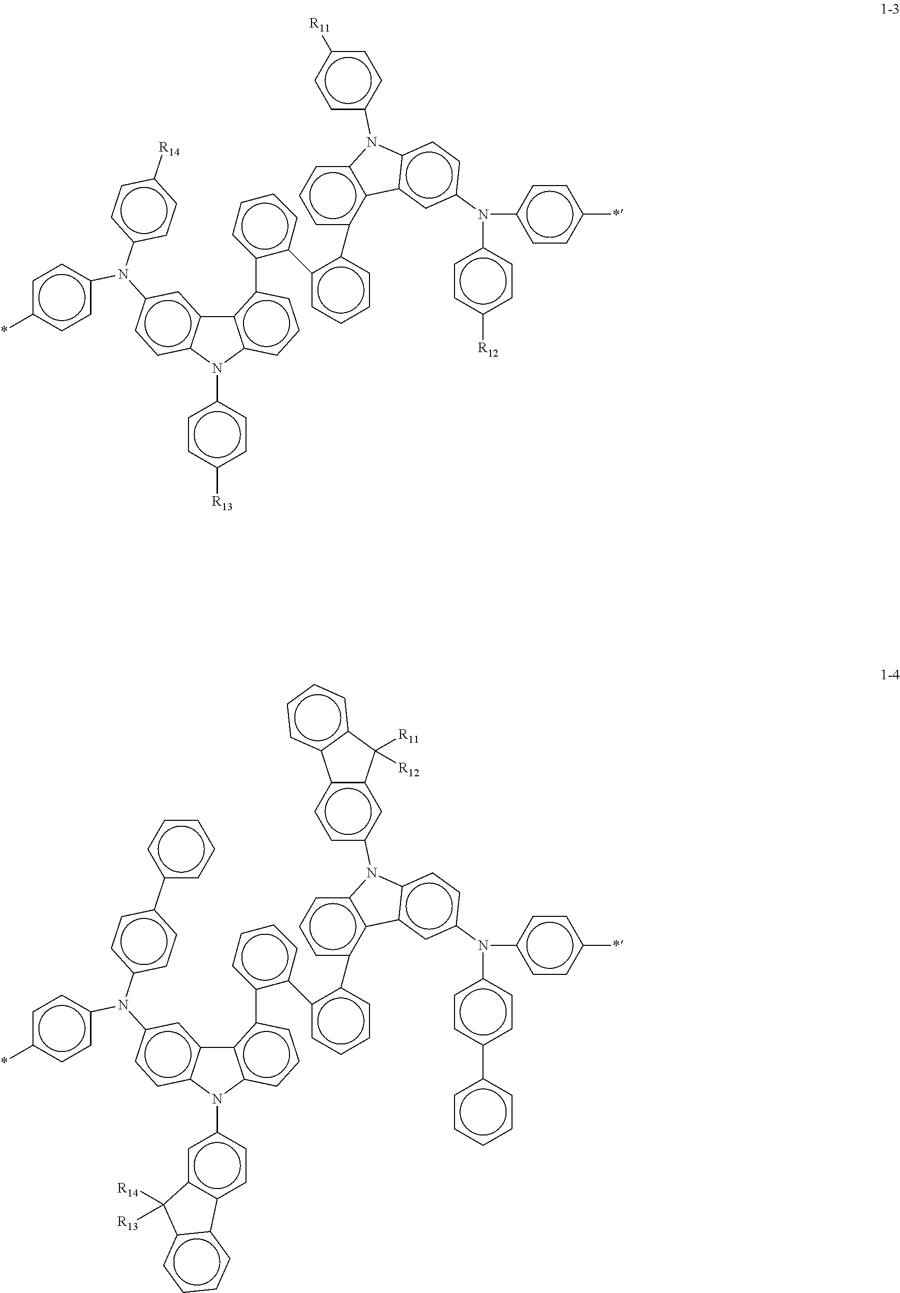

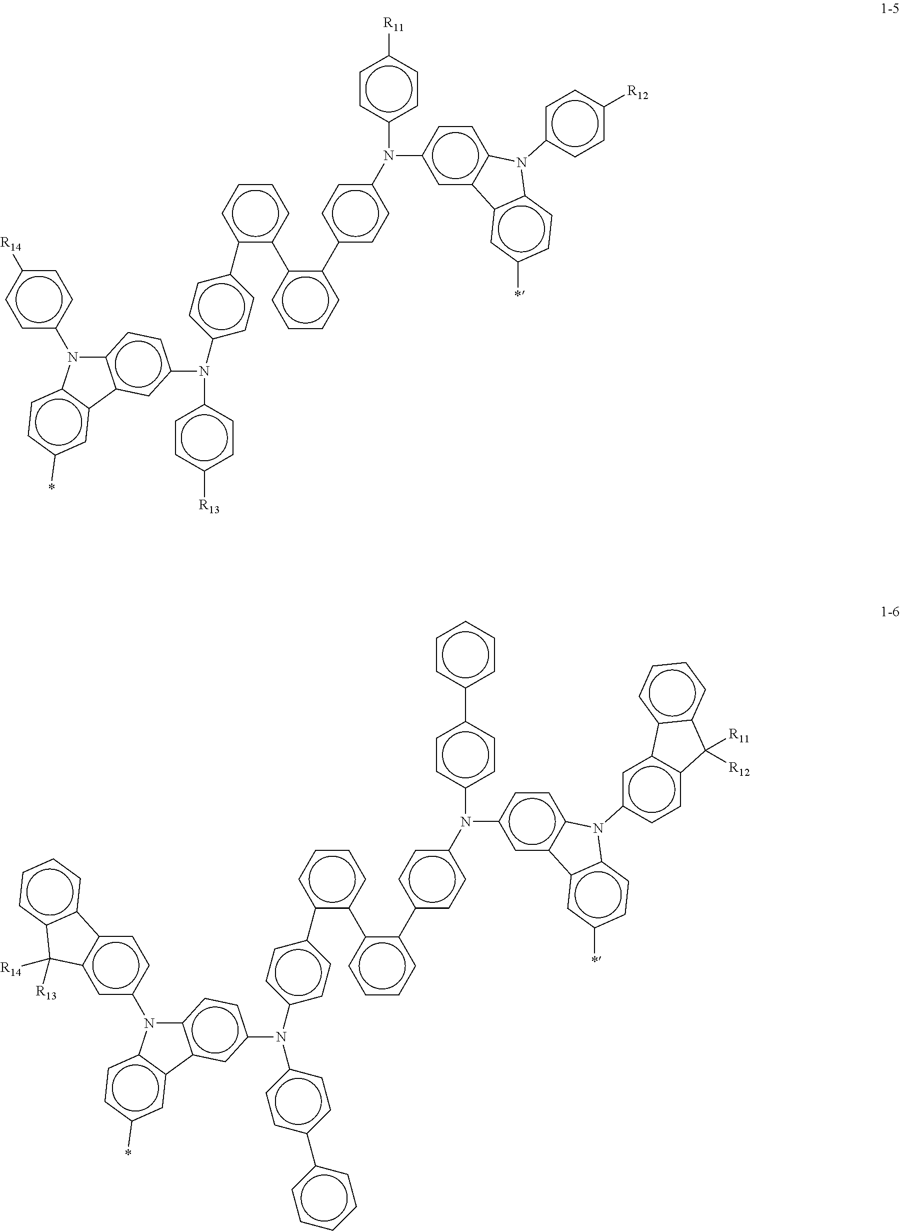

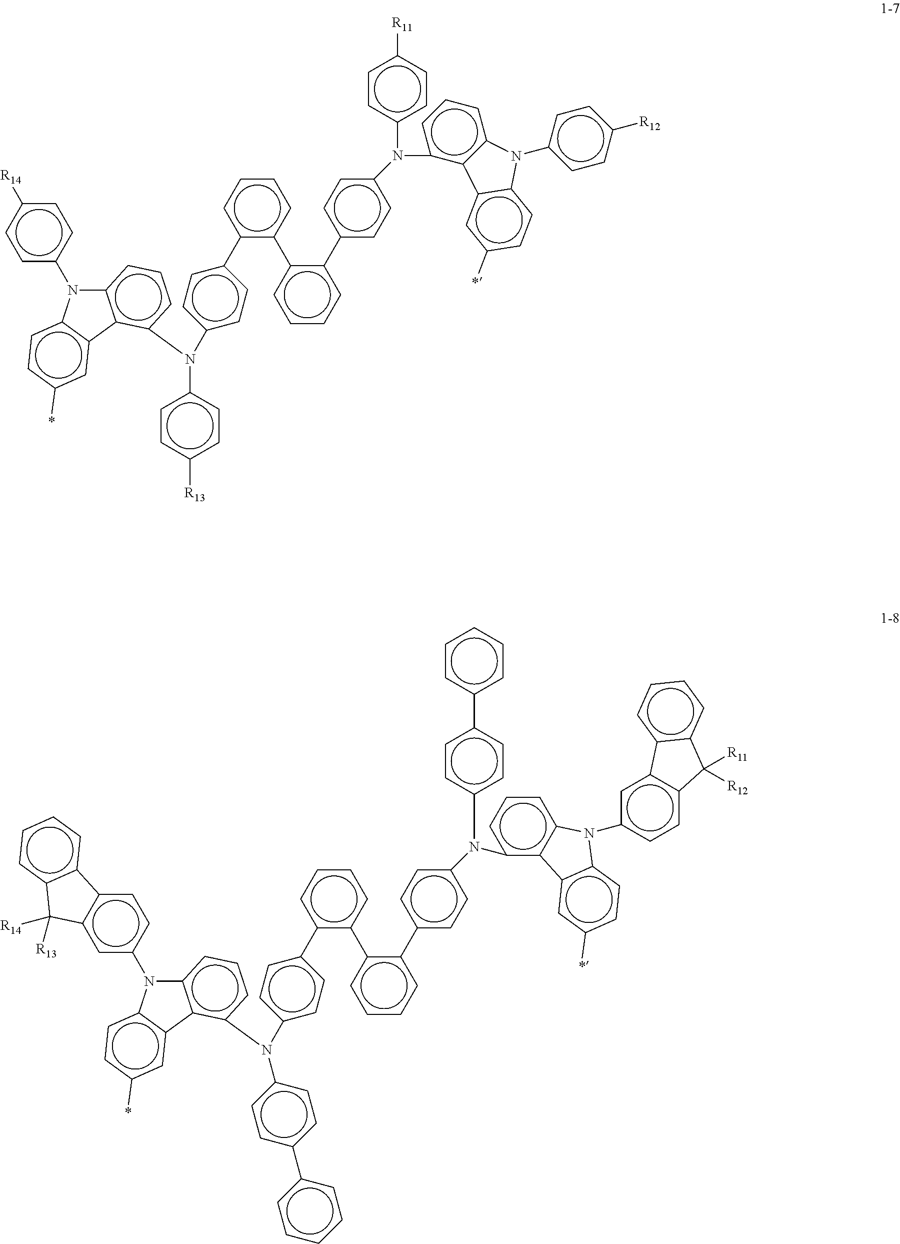

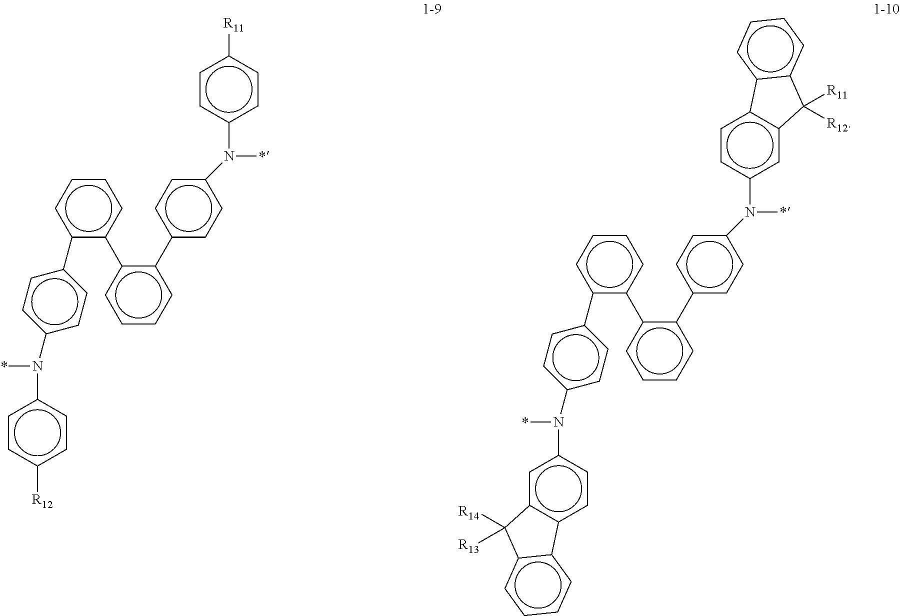

In Formulae 1-1 to 1-10,

R₁₁ to R₁₄ may each independently be hydrogen, deuterium, —F, —Cl, —Br, —I, a hydroxyl group, a cyano group, a nitro group, an amino group, or a C₁-C₆₀ alkyl group, and

* and *′ each indicate a binding site to a neighboring atom.

The first repeating unit has a high triplet energy level because of a structure in which two arylamine groups (X₁ and X₂ in Formula 1) are linked via two o-phenylene groups (portions except for X₁ and X₂ in Formula 1; also referred to as “linker”). Therefore, current efficiency may be improved by applying the polymer compound including the first repeating unit to an organic light-emitting device. Also, the polymer compound including the first repeating unit has high charge mobility. Thus, in particular, when the polymer compound including the first repeating unit is used as a hole transport material of the organic light-emitting device, degradation caused by electrons is reduced to thereby increase an emission lifespan of the organic light-emitting device.

Also, the first repeating unit controls flexibility of the first repeating unit by introducing a linker in which two o-phenyl groups are linked to two aryl amine groups, thereby improving solubility and heat resistance of the polymer compound to the solvent.

An amount of the first repeating unit in the polymer compound is not particularly limited, and may be adjusted by taking into account the triplet energy level and current efficiency of a layer formed using the polymer compound (for example, a hole injection layer or a hole transport layer). In an embodiment, the amount of the first repeating unit may be in a range of about 35 parts by weight to about 95 parts by weight, for example, about 40 parts by weight to about 85 parts by weight, based on 100 parts by weight of the polymer compound.

When the polymer compound includes two or more first repeating units having different structures, the amount of the first repeating unit means a total amount of the two or more first repeating units having different structures.

Second Repeating Unit

The polymer compound includes a second repeating unit represented by Formula 3. For example, the polymer compound may include second repeating units having the same structure, or may include two or more second repeating units having different structures.

In an embodiment, the polymer compound may include two or more second repeating units having different structures.

In Formula 3, Ar₄ may be a substituted or unsubstituted C₅-C₃₀ carbocyclic group or a substituted or unsubstituted C₁-C₃₀ heterocyclic group.

In an embodiment, Ar₄ may be selected from:

a benzene group, a naphthalene group, a fluorene group, a spiro-bifluorene group, an indene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, a quinoline group, an isoquinoline group, a benzoquinoline group, a quinoxaline group, a quinazoline group, a carbazole group, a benzimidazole group, a benzofuran group, a benzothiophene group, an isobenzothiophene group, a benzoxazole group, an isobenzoxazole group, a triazole group, a tetrazole group, an oxadiazole group, a triazine group, a dibenzofuran group, and a dibenzothiophene group; and

a benzene group, a naphthalene group, a fluorene group, a spiro-bifluorene group, an indene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, a quinoline group, an isoquinoline group, a benzoquinoline group, a quinoxaline group, a quinazoline group, a carbazole group, a benzimidazole group, a benzofuran group, a benzothiophene group, an isobenzothiophene group, a benzoxazole group, an isobenzoxazole group, a triazole group, a tetrazole group, an oxadiazole group, a triazine group, a dibenzofuran group, and a dibenzothiophene group, each substituted with at least one selected from deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, an adamantanyl group, a norbornanyl group, a norbornenyl group, a phenyl group, a biphenyl group, a terphenyl group, a naphthyl group, a fluorenyl group, a pyridinyl group, a pyrazinyl group, a pyrimidinyl group, a pyridazinyl group, a triazinyl group, a quinolinyl group, an isoquinolinyl group, a quinoxalinyl group, a quinazolinyl group, a carbazolyl group, a dibenzofuranyl group, and a dibenzothiophenyl group.

In one or more embodiments, Ar₄ may be a substituent represented by one selected from Formulae C-1 to C-4:

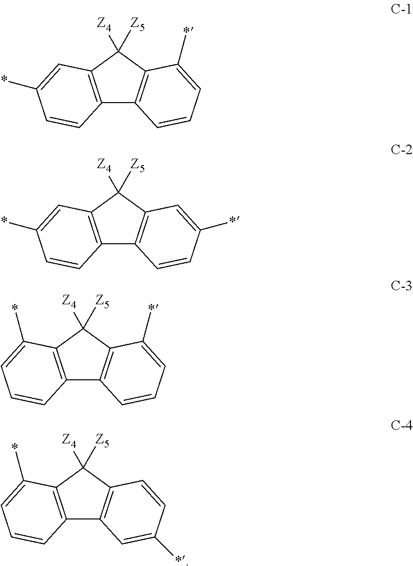

In Formulae C-1 to C-4,

Z₄ and Z₅ may each independently be selected from -(L₁)ₘ₁-(Q₁)ₙ₁, hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,

at least one of Z₄ and Z₅ may be -(L₁)ₘ₁-(Q₁)ₙ₁, and

* and *′ each indicate a binding site to a neighboring atom.

In an embodiment, Z₄ and Z₅ may each be -(L₁)ₘ₁-(Q₁)ₙ₁, the description provided in connection with Z₁ in Formulae A-1 to A-6 may be applied thereto, and at least one of Z₄ and Z₅ may be -(L₁)ₘ₁-(Q₁)ₙ₁.

In an embodiment, Ar₄ may be a substituent represented by Formula C-2, but embodiments of the present disclosure are not limited thereto.

L₁ in Formula 3 may be selected from a single bond, a substituted or unsubstituted C₁-C₆₀ alkylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group.

In an embodiment, L₁ may be selected from:

a single bond, a C₁-C₆₀ alkylene group, a phenylene group, a naphthylene group, a fluorenylene group, a spiro-bifluorenylene group, a triphenylenylene group, and a carbazolylene group; and

a C₁-C₆₀ alkylene group, a phenylene group, a naphthylene group, a fluorenylene group, a spiro-bifluorenyl group, a triphenylenylene group, and a carbazolylene group, each substituted with at least one selected from deuterium, —F, —Cl, —Br, —I, a hydroxyl group, a cyano group, a nitro group, an amidino group, a hydrazine group, a hydrazone group, a C₁-C₂₀ alkyl group, a C₁-C₂₀ alkoxy group, a phenyl group, a carbazole group, a fluorenyl group, and a triphenylenyl group.

In Formula 3, m1 may be an integer from 1 to 5, wherein, when m1 is two or more, two or more groups L₁ may be identical to or different from each other. For example, m1 may be 1 or 2, but embodiments of the present disclosure are not limited thereto.

Q₁ in Formula 3 is a crosslinking group. The crosslinking group is not particularly limited as long as the crosslinking group can induce a crosslinking reaction by thermal energy or light energy, and the crosslinking group may be selected by taking into account the film-forming property of the polymer compound.

In an embodiment, Q₁ may be a monovalent crosslinking group including at least one selected from an ether group, a vinyl group, an acrylate group, a methacrylate group, a styryl group, an epoxy group, an oxetane group, and a benzocyclobutene group.

In an embodiment, Q₁ in Formula 3 may be a crosslinking group represented by one of Formulae Q-1 to Q-8:

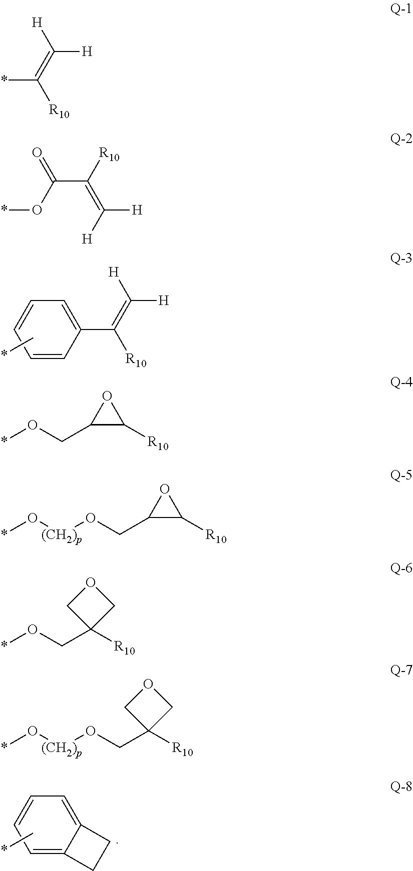

In Formulae Q-1 to Q-8,

R₁₀ may be hydrogen, deuterium, —F, —Cl, —Br, —I, a hydroxyl group, a cyano group, a nitro group, an amino group, or a C₁-C₁₀ alkyl group,

p may be an integer from 1 to 10, and

* indicates a binding site to a neighboring atom.

In an embodiment, R₁₀ may be hydrogen, a methyl group, an ethyl group, a propyl group, an iso-butyl group, a sec-butyl group, a tert-butyl group, a pentyl group, an iso-amyl group, or a hexyl group, but embodiments of the present disclosure are not limited thereto.

In an embodiment, p may be an integer from 1 to 5, for example, 1 or 2.

In an embodiment, for example, a benzocyclobutene ring such as cyclo[4,2,0]octa-1,3,5-triene group may be used as Q₁ by taking into account the crosslinkability, the structural stability of the crosslinked structure, and the electrochemical stability of the second repeating unit.

cyclo[4,2,0]octa-1,3,5-triene group

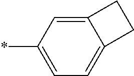 [SMILES: *c1ccc2c(c1)CC2]

In one or more embodiments, a ring-type ether group such as an epoxy group or an oxetane group, or a vinyl ether group may be used as Q₁ by taking into account the crosslinkability of the second repeating unit.

p1 in Formula 3 may be an integer from 1 to 5, wherein, when p1 is two or more, two or more groups -(L₁)ₘ₁-(Q₁)ₙ₁ may be identical to or different from each other. In an embodiment, p1 may be 1 or 2.

In an embodiment, the second repeating unit may be represented by Formula 3-1 or 3-2:

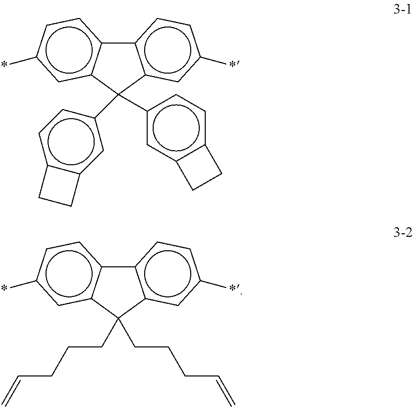

In Formulae 3-1 and 3-2,

* and *′ each indicate a binding site to a neighboring atom.

An amount of the second repeating unit is not particularly limited, and may be adjusted by taking into the film-forming property of the second polymer compound. In an embodiment, the amount of the second repeating unit may be in a range of about 1 part by weight to about 15 parts by weight, for example, about 5 parts by weight to about 10 parts by weight, based on 100 parts by weight of the polymer compound.

When the polymer compound includes two or more second repeating units having different structures, the amount of the second repeating unit means a total amount of the two or more second repeating units having different structures.

The second repeating unit represented by Formula 3 includes a crosslinking group (Q₁ in Formula 3). Therefore, by introducing the second repeating unit, the film-forming property may be improved by using solution coating.

Third Repeating Unit

The polymer compound may further include a third repeating unit represented by Formula 4. For example, the polymer compound may include third repeating units having the same structure, or may include two or more third repeating units having different structures.

Ar₅ Formula 4

In Formula 4, Ar₅ may be a substituted or unsubstituted C₅-C₃₀ carbocyclic group or a substituted or unsubstituted C₁-C₃₀ heterocyclic group.

In Formula 4, the description provided in connection with Ar₁ to Ar₃ in Formula 2 or the description provided in connection with Ar₄ in Formula 3 may be applied to Ar₅.

In an embodiment, the third repeating unit may be represented by one of Formulae 4-1 to 4-5:

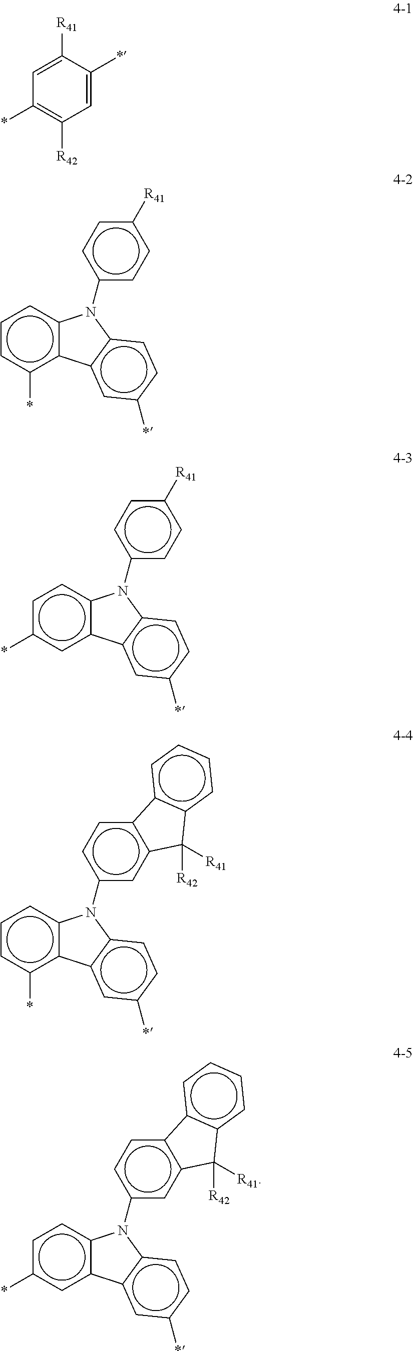

In Formulae 4-1 to 4-5,

R₄₁ and R₄₂ may each independently be hydrogen, deuterium, —F, —Cl, —Br, —I, a hydroxyl group, a cyano group, a nitro group, an amino group, or C₁-C₆₀ alkyl group, and

* and *′ each indicate a binding site to a neighboring atom.

In an embodiment, the third repeating unit may be represented by Formula 4-1 or 4-5, but embodiments of the present disclosure are not limited thereto.

An amount of the third repeating unit is not particularly limited, and may be adjusted by taking into account the solubility of the polymer compound in a solvent. In an embodiment, the amount of the third repeating unit may be in a range of about 1 part by weight to about 60 parts by weight, for example, about 10 parts by weight to about 50 parts by weight, based on 100 parts by weight of the polymer compound.

In one or more embodiments, the amount of the third repeating unit may be in a range of about 40 parts by weight to about 60 parts by weight based on 100 parts by weight of the polymer compound.

When the polymer compound includes two or more third repeating units having different structures, the amount of the third repeating unit means a total amount of the two or more third repeating units.

Since the polymer compound including the third repeating unit has excellent solubility in a solvent, the film formation using solution coating may be facilitated by introducing the third repeating unit into the polymer compound.

The polymer compound may include the first repeating unit and the second repeating unit, and may further include the third repeating unit.

Therefore, as described above, since the polymer compound includes the first repeating unit, the polymer compound has a high triplet energy level, and high efficiency may be achieved when the polymer compound is applied to an organic light-emitting device. Also, since charge mobility of the polymer compound is improved, an organic light-emitting device manufactured by using the polymer compound as a hole transport material may exhibit high luminescent efficiency.

Also, since the polymer compound includes the second repeating unit, the film-forming property thereof is excellent, and thus, the film formation using solution coating is possible. Therefore, a large-area organic light-emitting device may be provided and mass production may be improved.

In addition, when the polymer compound further includes the third repeating unit, the solubility of the polymer compound in the solvent is high and the film formation using solution coating is facilitated.

In an embodiment, the polymer compound may be a 2-element copolymer(i.e., bipolymer) including the first repeating unit and the second repeating unit or a 3-element copolymer(i.e., terpolymer) including the first repeating unit, the second repeating unit, and the third repeating unit. However, the polymer compound is not limited thereto, and may further include other repeating units except for the first repeating unit, the second repeating unit, or the third repeating unit.

In an embodiment, the structure of the polymer compound is not particularly limited, and may be a random copolymer, an alternating copolymer, a periodic copolymer, or a block copolymer.

The number average molecular weight (Mn) of the polymer compound is not particularly limited as long as the effects of the present disclosure can be obtained. In an embodiment, the number average molecular weight of the polymer compound may be in a range of about 5,000 Daltons to about 500,000 Daltons, for example, about 9,000 Daltons to about 85,000 Daltons. When the number average molecular weight is within this range, a layer having a uniform thickness may be formed by appropriately adjusting a viscosity of a composition including the polymer compound.

In an embodiment, the weight average molecular weight of the polymer compound is not particularly limited as long as the effects of the present disclosure can be obtained. In an embodiment, the weight average molecular weight of the polymer compound may be in a range of about 10,000 Daltons to about 1,000,000 Daltons, for example, about 15,000 Daltons to about 180,000 Daltons. While not wishing to be bound by theory, it is understood that when the weight average molecular weight is within this range, a layer having a uniform thickness may be formed by appropriately adjusting a viscosity of a composition including the polymer compound.

The number average molecular weight (Mn) and the weight average molecular weight (Mw) were measured and calculated by the following method. However, the method of measuring the number average molecular weight (Mn) and the weight average molecular weight (Mw) is not particularly limited, and known methods may be applied thereto.

Measurement of number average molecular weight (Mn) and weight average molecular weight (Mw)

The number average molecular weight (Mn) and the weight average molecular weight (Mw) were measured under the following conditions by gel permeation chromatography (GPC) using polystyrene as a standard sample.

Analysis apparatus: Prominance (manufactured by Shimadzu Corporation)

Column: PLgel MIXED-B (manufactured by Polymer Laboratories Inc.)

Column temperature: 40° C.

Flow rate: 1.0 milliliters per minute (mL/min)

Dose: 20 microliters (μL)

Solvent: tetrahydrofuran (THF) (concentration: about 0.05 percent by weight, wt %)

Detector: UV-VIS detector (SPD-10AV, manufactured by Shimadzu Corporation)

Standard sample: Polystyrene

The main chain terminal of the polymer compound may be appropriately defined according to a type of a material used. For example, the main chain terminal of the polymer compound may be a hydrogen atom, but embodiments of the present disclosure are not limited thereto.

The polymer compound may be easily understood and prepared by those of ordinary skill in the art by referring to known organic synthesis methods or Examples provided below.

For example, the polymer compound may be prepared by using a copolymerization reaction by using at least one first monomer represented by Formula 11 and at least one second monomer represented by Formula 12 and/or at least one third monomer represented by Formula 13.

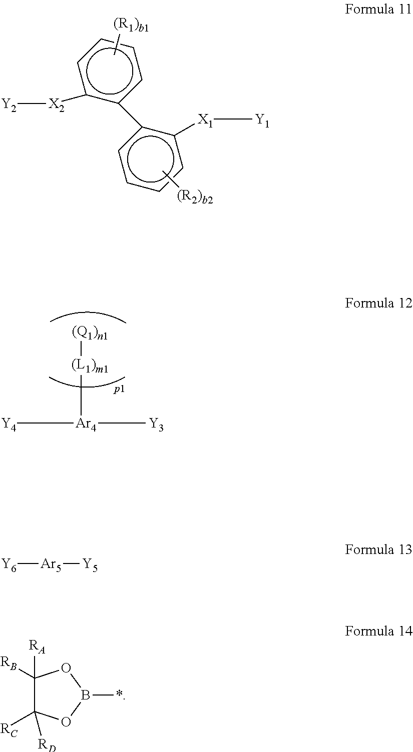

In Formula 11 to 13,

X₁, X₂, R₁, R₂, b1, b2, Ar₄, L₁, m1, Q₁, n1, p1, and Ar₅ are the same as described in Formulae 1 to 4,

Y₁ to Y₆ may each independently be —F, —Cl, —Br, —I, or a substituent represented by Formula 14,

wherein in Formula 14,

R_{A} to R_{D} may each independently be a C₁-C₃ alkyl group, and

* indicates a binding site to a neighboring atom.

The first monomer, the second monomer, and the third monomer may be synthesized according to a known synthesis method, and the structures thereof may be identified by a known method, for example, NMR and LC-MS.

The polymer compound may be used as a material for an organic light-emitting device and may provide a material for an organic light-emitting device, which has high current efficiency and high charge mobility because of a high triplet energy level.

Also, since the first repeating unit in the polymer compound has a flexible structure as described above, the polymer compound has a high solubility in a solvent and a high heat resistance, thereby facilitating a film formation using solution coating.

Composition for Manufacturing Organic Light-Emitting Device

Another aspect of the present disclosure provides a composition for manufacturing an organic light-emitting device, which includes the polymer compound and a liquid medium.

The polymer compound described above or the material for the organic light-emitting device, which includes the polymer compound, has high charge mobility and thus may be used as a hole injection material, a hole transport material, or a material for forming an emission layer. In an embodiment, the polymer compound and the material for the organic light-emitting device, which includes the polymer compound, may be used as a hole injection material or a hole transport material (for example, a hole transport material)in terms of hole transport capability.

In an embodiment, the composition for manufacturing the organic light-emitting device may include the polymer compound, and at least one selected from a hole transport material, an electron transport material, and a light-emitting material.

In an embodiment, the light-emitting material may be an organometallic complex compound, but embodiments of the present disclosure are not limited thereto.

The composition for manufacturing the organic light-emitting device may include the polymer compound and a liquid medium. The composition for manufacturing the organic light-emitting device may be used for forming each layer of the organic light-emitting device by solution coating.

The liquid medium may be a liquid medium (for example, a solvent) that enables the material for the organic light-emitting device to be dissolved. That is, the composition for the organic light-emitting device may be a solution composition.

Examples of the liquid medium may include toluene, xylene, ethylbenzene, diethylbenzene, mesitylene, propylbenzene, cyclohexylbenzene, dimethoxybenzene, anisole, ethoxy toluene, phenoxytoluene, iso-propylbiphenyl, dimethylanisole, phenyl acetate, phenyl propionic acid, methyl benzoate, and ethyl benzoate, but embodiments of the present disclosure are not limited thereto.

In the composition for manufacturing the organic light-emitting device, a concentration of the material for the organic light-emitting device may be adjusted according to usage.

Another aspect of the present disclosure provides a method of manufacturing an organic light-emitting device, which includes a first electrode, a second electrode, and an organic layer disposed between the first electrode and the second electrode, wherein the organic layer includes an emission layer and the polymer compound, wherein the method includes forming a layer including the polymer compound by solution coating using the composition including the polymer compound and the liquid medium.

### Organic Light-Emitting Device

Hereinafter, with reference to the FIGURE, an embodiment of an organic light-emitting device will be described in detail. The FIGURE is a schematic view of an organic light-emitting device according to an embodiment.

An organic light-emitting device 100 according to an example embodiment may include a substrate 110, a first electrode 120 on the substrate 110, a hole injection layer 130 on the first electrode 120, a hole transport layer 140 on the hole injection layer 130, an emission layer 150 on the hole transport layer 140, an electron transport layer 160 on the emission layer 150, an electron injection layer 170 on the electron transport layer 160, and a second electrode 180 on the electron injection layer 170.

In the organic light-emitting device 100, the polymer compound represented by Formula 1 may be, for example, included in at least one organic layer (e.g., at least one organic layer selected from the hole injection layer 130, the hole transport layer 140, the emission layer 150, the electron transport layer 160, and the electron injection layer 170 between the first electrode 120 and the second electrode 180. In some embodiments, the polymer compound represented by Formula 1 may be included in the emission layer 150 as a hole transport host. In some embodiments, the polymer compound represented by Formula 1 may be included in an organic layer other than the emission layer 150. For example, the polymer compound represented by Formula 1 may be included in the hole injection layer 130 and/or the hole transport layer 140 as a hole transport material.

An organic layer including the polymer compound represented by Formula 1 may be formed by, for example, solution coating. In some embodiments, the organic layer including the polymer compound represented by Formula 1 may be formed by solution coating, such as spin coating, casting, micro-gravure coating, gravure coating, bar coating, roll coating, wire bar coating, dip coating, spray coating, screen printing, flexographic printing, offset printing, or ink-jet printing.

In the solution coating, a material for an organic light-emitting device including the polymer compound represented by Formula 1 may be coated to form an organic layer. In this embodiment, the material for an organic light-emitting device may include a solvent. Examples of the material for an organic light-emitting device including the solvent include an ink composition used in ink-jet printing and a film-forming composition used in spin coating, but embodiments are not limited thereto.

Also, the solvent, included in the material for the organic light-emitting device, for use in the solution coating is not particularly limited as long as the solvent can dissolve the polymer compound represented by Formula 1 and may be appropriately selected according to the type of the polymer compound. For example, examples of the solvent may include toluene, xylene, ethylbenzene, diethylbenzene, mesitylene, propylbenzene, cyclohexylbenzene, dimethoxybenzene, anisole, ethoxy toluene, phenoxytoluene, iso-propylbiphenyl, dimethylanisole, phenyl acetate, phenyl propionic acid, methyl benzoate, and ethyl benzoate, but embodiments of the present disclosure are not limited thereto. An amount of the solvent used is not particularly limited. The concentration of the polymer compound may be in a range of 0.1 wt % to about 10 wt %, for example, about 0.5 wt % to about 5 wt %, by taking into account the coatability thereof.

Also, a method of depositing layers other than the organic layer including the polymer compound is not particularly limited. The layers other than the organic layer including the polymer may be formed by, for example, vacuum deposition or solution coating.

The substrate 110 may be any suitable substrate generally used in organic light-emitting devices. For example, the substrate 110 may be a glass substrate, a semiconductive substrate such as a silicon substrate, or a transparent plastic substrate, but embodiments of the present disclosure are not limited thereto.

The first electrode 120 may be formed on the substrate 110. The first electrode 120 may be, for example, an anode, and be formed of a material with a high work function selected from a metal, an alloy, or a conductive compound. For example, the first electrode 120 may be a transparent electrode including indium tin oxide (In₂O₃—SnO₂, ITO), indium zinc oxide (In₂O₃—ZnO), tin oxide (SnO₂), or zinc oxide (ZnO), each having excellent transparency and conductivity. The first electrode 120 may be a reflective electrode that may be formed by stacking magnesium (Mg) or aluminum (Al) on the transparent electrode.

The hole injection layer 130 may be formed on the first electrode 120. The hole injection layer 130 may facilitate hole injection from the first electrode 120. In some embodiments, the hole injection layer 130 may be formed to a thickness in a range of about 10 nanometers (nm) to about 1,000 nm, and in some embodiments, about 10 nm to about 100 nm.

The hole injection layer 130 may include a known hole injection material. Examples of the known hole injection material forming the hole injection layer 130 include poly(ether ketone)-containing triphenylamine (TPAPEK), 4-iso-propyl-4′-methyl diphenyl iodonium tetrakis (pentafluorophenyl) borate (PPBI), N,N′-diphenyl-N,N′-bis-[4-(phenyl-m-tolyl-amino)-phenyl]-biphenyl-4,4′-diamine (DNTPD), copper phthalocyanine, 4,4′,4″-tris(3-methyl phenyl phenyl amino) triphenylamine (m-MTDATA), N,N′-di(1-naphthyl)-N,N′-diphenylbenzidine (NPB), 4,4′,4″-tris (diphenyl amino) triphenylamine (TDATA), 4,4′,4″-tris(N,N-2-naphthyl phenyl amino) triphenylamine (2-TNATA), polyaniline/dodecylbenzene sulphonic acid (PANI/DBSA), poly(3,4-ethylenedioxythiophene)/poly(4-styrene sulfonate (PEDOT/PSS), polyaniline/10-camphor sulfonic acid (PANI/CSA), and polyaniline/poly(4-styrene sulfonate (PANI/PSS).

The hole transport layer 140 may be formed on the hole injection layer 130. The hole transport layer 140 may facilitate hole transport. In some embodiments, the hole transport layer 140 may be formed to a thickness in a range of about 10 nm to about 150 nm. The hole transport layer 140 may include the polymer compound represented by Formula 1. Since the hole transport layer 140 includes the polymer compound according to the embodiment, the current efficiency and emission lifespan of the organic light-emitting device 100 may be improved. When a film is formed by wet deposition, a film may be efficiently formed to a large area by using the polymer compound.

The hole transport layer 140 may further include a known hole transport material. Examples of the known hole transport material include carbazole derivatives, e.g., 1,1-bis[(di-4-tolylamino)phenyl] cyclohexane (TAPC), N-phenylcarbazole, and polyvinylcarbazole, and N,N′-bis(3-methylphenyl)-N,N′-diphenyl-[1,1-biphenyl]-4,4′-diamine (TPD), 4,4′,4″-tris(N-carbazolyl) triphenylamine (TCTA), N,N′-di(1-naphthyl)-N,N′-diphenylbenzidine (NPB), and poly(9,9-dioctyl-fluorene-co-N-(4-butylphenyl)-diphenylamine (TFB).

The emission layer 150 may be formed on the hole transport layer 140. The emission layer 150 emits light by fluorescence or phosphorescence. The emission layer 150 may include a known electron transport host (ET-host) material and a known dopant material.

The emission layer 150 may be formed by solution coating, e.g., spin coating or ink-jet coating. The emission layer 150 may be, for example, formed to a thickness in a range of about 10 nm to about 60 nm.

In the organic light-emitting device 100 according to an embodiment, a dopant material included in the emission layer 150 may be capable of emitting light from triplet excitons (i.e., emission by phosphorescence). In this embodiment, the organic light-emitting device 100 may have an improved emission lifespan.

Examples of an HT-host material or the ET-host material in the emission layer 150 include tris(8-quinolinato)aluminum (Alq₃), 4,4′-bis(carbazol-9-yl)biphenyl (CBP), poly(n-vinylcarbazole (PVK), 9,10-di(naphthalene-yl)anthracene (ADN), 4,4′,4″-tris(N-carbazolyl)triphenylamine (TCTA), 1,3,5-tris(N-phenyl-benzimidazol-2-yl)benzene (TPBI) 3-tert-butyl-9,10-di(naphth-2-yl)anthracene (TBADN), distyrylarylene (DSA), and 4,4′-bis(9-carbazole)-2,2′-dimethyl-biphenyl (dmCBP).

In addition, the emission layer 150 may include, as a dopant material, perylene or a derivative thereof, rubrene or a derivative thereof, coumarin or a derivative thereof, 4-dicyanomethylene-2-(p-dimethylaminostyryl)-6-methyl-4H-pyran (DCM) or a derivative thereof, an iridium complex, e.g., bis[2-(4,6-difluorophenyl)pyridinate] picolinate iridium (III) (Flrpic), bis(1-phenylisoquinoline)(acetylacetonate) iridium (III) (Ir(piq)₂(acac)), or tris(2-phenylpyridine) iridium (III) (Ir(ppy)₃), an osmium complex, or a platinum complex. For example, the light-emitting material may be an organometallic light-emitting complex compound.

The electron transport layer 160 may be formed on the emission layer 150. The electron transport layer 160 may serve to transport electrons, and may be formed by vacuum deposition, spin coating, or ink-jet printing. The electron transport layer 160 may be, for example, formed to a thickness in a range of about 15 nm to about 50 nm.

The electron transport layer 160 may include a known electron transport material. Examples of the known electron transport material include tris(8-quinolinato) aluminum (Alq₃) and a compound including a nitrogen-containing aromatic ring. Examples of the compound including a nitrogen-containing aromatic ring include a compound including a pyridine ring such as 1,3,5-tri[(3-pyridyl)-phen-3-yl]benzene, a compound including a triazine ring such as 2,4,6-tris(3′-(pyridin-3-yl)biphenyl-3-yl)-1,3,5-triazine, and a compound including an imidazole ring such as 2-(4-(N-phenylbenzimidazolyl-1-yl-phenyl)-9,10-dinaphthylanthracene. In some embodiments, as an electron transport material, a commercially available item may also be used. Examples of the commercially available item include KLET-01, KLET-02, KLET-03, KLET-10, and KLET-M1 (available from Chemipro Kasei Corporation).

The electron injection layer 170 may be formed on the electron transport layer 160. The electron injection layer 170 may facilitate electron injection from the second electrode 180, and may be formed by vacuum deposition. In some embodiments, the electron injection layer 170 may be formed to a thickness in a range about 0.3 nm to about 9 nm. The electron injection layer 170 may include a known electron injection material. For example, the electron injection layer 170 may be formed of a lithium compound, e.g., (8-hydroxyquinolinato)lithium (Liq) or lithium fluoride (LiF), sodium chloride (NaCl), cesium fluoride (CsF), lithium oxide (Li₂O), or barium oxide (BaO).

The second electrode 180 may be formed on the electron injection layer 170. The second electrode 180 may be a cathode, and be formed of a material with a low work function selected from a metal, an alloy, and a conductive compound. For example, the second electrode 180 may be formed as a reflective electrode including a metal, e.g., lithium (Li), magnesium (Mg), aluminum (Al), or calcium (Ca), or an alloy, e.g., an aluminum-lithium (Al—Li) alloy, a magnesium-indium (Mg—In) alloy, or a magnesium-silver (Mg—Ag) alloy. In some embodiments, the second electrode 180 may be formed as a transparent electrode having a thickness of 20 nm or less and including a thin film of the metal or the alloy, or a transparent conductive film including indium tin oxide (In₂O₃—SnO₂) or indium zinc oxide (In₂O₃—ZnO).

The organic light-emitting device 100 according to an embodiment includes an organic layer including the bicarbazole compound represented by Formula 1, and thus, may have improved luminous efficiency and an improved emission lifespan.

Furthermore, a stacking structure of the organic light-emitting device 100 according to an embodiment is not limited to the foregoing description. The organic light-emitting device 100 according to an embodiment may have a different stacking structure known in the art. For example, the organic light-emitting device 100 may not include at least one selected from the hole injection layer 130, the hole transport layer 140, the electron transport layer 160, and the electron injection layer 170, or may further include another layer. In some embodiments, each layer of the organic light-emitting device 100 may be formed as a single layer or as multiple layers.

For example, in order to prevent diffusion of excitons or holes to the electron transport layer 160, the organic light-emitting device 100 may further include a hole blocking layer between the hole transport layer 140 and the emission layer 150. The hole blocking layer may be formed using, for example, an oxadiazole derivative, a triazole derivative, or a phenanthroline derivative.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, an n-propyl group, an iso-propyl group, an n-butyl group, an iso-butyl group, a sec-butyl group, a tert-butyl group, an n-pentyl group, an iso-pentyl group, a tert-pentyl group, a neo-pentyl group, a 1,2-dimethylpropyl group, an n-hexyl group, an iso-hexyl group, a 1,3-dimethylbutyl group, a 1-iso-propylpropyl group, a 1,2-dimethylbutyl group, an n-heptyl group, a 1,4-dimethylpentyl group, a 3-ethylpentyl group, a 2-methyl-1-iso-propylpropyl group, a 1-ethyl-3-methylbutyl group, an n-octyl group, a 2-ethylhexyl group, a 3-methyl-1-iso-propylbutyl group, a 2-methyl-1-iso-propyl group, a 1-tert-butyl-2-methylpropyl group, an n-nonyl group, a 3,5,5-trimethyldecyl group, an n-decyl group, an iso-decyl group, an n-undecyl group, a 1-methyldecyl group, an n-dodecyl group, an n-tridecyl group, an n-tetradecyl group, an n-pentadecyl group, an n-hexadecyl group, an n-heptadecyl group, an n-octadecyl group, an n-nonadecyl group, an n-eicosyl group, an n-heneicosyl group, an n-docosyl group, an n-tricosyl group, and an n-tetracosyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, a propoxy group, an iso-propoxy group, an n-butoxy group, an iso-butoxy group, a sec-butoxy group, a tert-butoxy group, an n-pentoxy group, an iso-pentoxy group, a tert-pentoxy group, a neo-pentoxy group, an n-hexyloxy group, an iso-hexyl group, a heptyloxy group, an octyloxy group, a nonyloxy group, a decyloxy group, an undecyloxy group, a dodecyloxy group, a tridecyloxy group, a tetradecyloxy group, a pentadecyloxy group, a hexadecyloxy group, a heptadecyloxy group, an octadecyloxy group, a 2-ethylhexyloxy group, and a 3-ethylpentyloxy group.

The term “C₂-C₆₀ alkenyl group” as used herein refers to a hydrocarbon group having at least one carbon-carbon double bond in the middle or at the terminus of a C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group having at least one carbon-carbon triple bond in the middle or at the terminus of a C₂-C₆₀ alkyl group, and examples thereof include an ethynyl group and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom selected from N, O, P, Si, and S as a ring-forming atom, in addition to 1 to 10 carbon atoms, and non-limiting examples thereof include a tetrahydrofuranyl group and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, and S as a ring-forming atom, 1 to 10 carbon atoms, and at least one carbon-carbon double bond in its ring. Examples of the C₂-C₁₀ heterocycloalkenyl group are a 2,3-dihydrofuranyl group and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group” as used herein refers to a monovalent group having a heterocyclic aromatic system that has at least one heteroatom selected from N, O, P, Si, and S as a ring-forming atom, in addition to 1 to 60 carbon atoms. The term “C₁-C₆₀ heteroarylene group” as used herein refers to a divalent group having a heterocyclic aromatic system that has at least one heteroatom selected from N, O, P, and S as a ring-forming atom, in addition to 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

The term “C₆-C₆₀ aryloxy group” as used herein refers to a group represented by —OA₁₀₂ (wherein A₁₀₂ is the C₆-C₆₀ aryl group), and the term “C₆-C₆₀ arylthio group” as used herein refers to a group represented by —SA₁₀₃ (wherein A₁₀₃ is the C₆-C₆₀ aryl group).

The term “monovalent non-aromatic condensed polycyclic group” as used herein refers to a monovalent group having two or more rings condensed to each other, only carbon atoms (for example, the number of carbon atoms may be in a range of 8 to 60) as ring-forming atoms, and no aromaticity in its entire molecular structure. A non-limiting example of the non-aromatic condensed polycyclic group is a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group having two or more rings condensed to each other, a heteroatom selected from N, O, P, Si, and S, other than carbon atoms (for example, the number of carbon atoms may be in a range of 2 to 60), as a ring-forming atom, and no aromaticity in its entire molecular structure. A non-limiting example of the monovalent non-aromatic condensed heteropolycyclic group is a carbazolyl group. The term “divalent non-aromatic condensed heteropolycyclic group” as used herein refers to a divalent group having the same structure as the monovalent non-aromatic condensed heteropolycyclic group.

At least one substituent of the substituted C₁-C₆₀ alkylene group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from:

deuterium, —F, —Cl, —Br, —I, —CD₃, —CD₂H, —CDH₂, —CF₃, —CF₂H, —CFH₂, —NCS, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, —NCS, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —N(Q₁₁)(Q₁₂) and —C(═O)(Q₁₁);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), and —C(═O)(Q₂₁); and

—Si(Q₃₁)(Q₃₂)(Q₃₃), —N(Q₃₁)(Q₃₂), and —C(═O)(Q₃₁), wherein

Q₁₁ to Q₁₃, Q₂₁ to Q₂₃, and Q₃₁ to Q₃₃ may each independently selected from hydrogen, deuterium, a C₁-C₂₀ alkyl group, a C₁-C₂₀ alkoxy group, a phenyl group, a pyridinyl group, a pyrimidinyl group, a triazinyl group, a biphenyl group, a phenylpyridinyl group, a phenylpyrimidinyl group, a phenyltriazinyl group, a diphenylpyridinyl group, a diphenylpyrimidinyl group, a diphenyltriazinyl group, a pyridinylphenyl group, a dipyridinylphenyl group, a pyrimidinylphenyl group, a dipyrimidinylphenyl group, a triazinylphenyl group, a ditriazinylphenyl group, a fluorenyl group, a spiro-bifluorenyl group, a dimethylfluorenyl group, a diphenylfluorenyl group, a carbazolyl group, a phenylcarbazolyl group, a biphenylcarbazolyl group, a dibenzofuranyl group, phenyldibenzofuranyl group, a diphenyldibenzofuranyl group, a dibenzothiophenyl group, a phenyldibenzothiophenyl group, and a diphenyldibenzothiophenyl group.

When a group containing a specified number of carbon atoms is substituted with any of the groups listed in the preceding paragraph, the number of carbon atoms in the resulting “substituted” group is defined as the sum of the carbon atoms contained in the original (unsubstituted) group and the carbon atoms (if any) contained in the substituent. For example, when the term “substituted C₁-C₃₀ alkyl” refers to a C₁-C₃₀ alkyl group substituted with C₆-C₃₀ aryl group, the total number of carbon atoms in the resulting aryl substituted alkyl group is C₇-C₆₀.

The term “biphenyl group” as used herein refers to a monovalent group in which two benzene groups are linked via a single bond.

The term “terphenyl group” as used herein refers to a monovalent group in which three benzene groups are linked via a single bond.

* and *′ used herein, unless defined otherwise, each indicate a binding site to a neighboring atom in a corresponding formula.

Embodiments of the present disclosure have been described with reference to the accompanying drawings, but the present disclosure is not limited thereto. It is apparent to those of ordinary skill in the art that various modifications or changes can be made thereto without departing from the technical idea set forth in the claims. It is understood that such modifications and changes also fall within the technical spirit and scope of the present disclosure.

Further, in Examples and Comparative Examples provided below, operations were carried out at room temperature (25° C.), unless otherwise indicated. Also, “%” and “parts” refer to “wt %” and “parts by weight”, respectively, unless otherwise indicated.

The wording “B was used instead of A” used in describing Synthesis Examples means that an identical molar equivalent of B was used in place of A.

### EXAMPLES

### Synthesis Example 1

### Synthesis of Compound 1

8.08 grams (g) (20.0 millimoles, mmol) of 1,4-dihexyl-2,5-dibromobenzene, 12.19 g (48.0 mmol) of bis(pinacolato)diboron, 0.98 g (1.2 mmol) of PdCl₂(dppf), 11.78 g (120.0 mmol) of potassium acetate, and 100 milliliters (ml) of 1,4-dioxane were mixed in a 300-mL flask in an argon atmosphere, and the mixture was heated and stirred for 6 hours under reflux.

After the reaction was completed, toluene and water were added to the reaction mixture, followed by liquid separation and washing with water. Sodium sulfate and activated charcoal were added thereto and filtering was performed thereon through Celite (registered trademark). A filtrate obtained therefrom was concentrated to obtain 11.94 g of a crude product.

The obtained product was recrystallized with hexane, and the crystals were washed with methanol. The obtained crystals were dried under reduced pressure to obtain 4.23 g of Compound 1 having white needle shapes. The structure of the obtained compound 1(yield: 42%) was identified by ¹H-NMR.

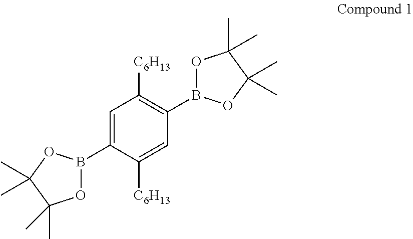

### Synthesis Example 2

### Synthesis of Compound 2

22.7 g (70.0 mmol) of 2,7-dibromofluorene, 21.9 g (147.0 mmol) of 5-bromo-1-pentene, 16.7 g (297.6 mmol) of potassium hydroxide, 1.2 g (7.2 mmol) of potassium iodide, and 170 ml of dimethylsulfoxide (DMSO) were mixed in a 500-mL four-neck flask in an argon atmosphere, and heated to a temperature of 80° C. for 4 hours.

After the reaction was completed, the reaction mixture was cooled to room temperature. Then, liquid separation was performed thereon by mixing 300 ml of water and 300 ml of toluene. An organic layer obtained therefrom was washed five times by using 300 ml of saturated brine. The obtained organic layer was dried by using sodium sulfate. Then, the residue obtained therefrom was purified by column chromatography and recrystallization to obtain 24.1 g of a white solid (yield: 75%). The structure of the obtained compound 2 was identified by ¹H-NMR.

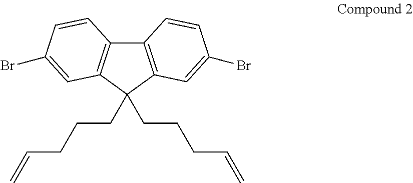 [SMILES: C=CCCCC1(CCCC=C)c2cc(Br)ccc2-c2ccc(Br)cc21]

### Synthesis Example 3

### Synthesis of Compound 3

Synthesis of Compound 3-1

4.1 g (22.4 mmol) of 3-bromobenzocyclobutane and 69 ml of tetrahydrofuran were cooled to −78° C. in a dry ice-methanol bath in a reaction vessel in an argon atmosphere. 6.9 ml of n-BuLi was added thereto, and the mixture was stirred for 2 hours. A solution, in which 4.1 g of 4,4′-dibromo-[1,1′-biphenyl]-2-carboxylic acid methyl ester was dissolved in 12 mL of tetrahydrofuran, was added dropwise thereto. The reaction mixture was stirred at a temperature of −78° C. for 2 hours and then stirred at room temperature for 4 hours. 50 ml of water was slowly added thereto while the reaction mixture was cooled in an ice bath. Then, the reaction mixture was transferred to a separatory funnel and washed twice with 30 mL of water. An organic layer obtained therefrom was dried by using magnesium sulfate, a solid obtained therefrom was filtered, and a solution was concentrated to obtain 5.6 g of a solid (yield: 92%). The structure of the obtained Compound 3-1 was identified by ¹H-NMR.

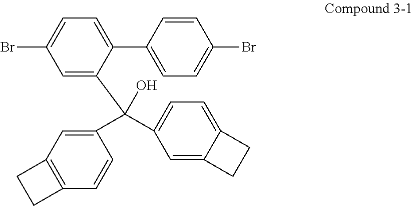 [SMILES: OC(c1ccc2c(c1)CC2)(c1ccc2c(c1)CC2)c1cc(Br)ccc1-c1ccc(Br)cc1]

3-2. Synthesis of Compound 3

5.0 g (9.1 mmol) of Compound 3-1 and 24 mL of chloroform were added to a reaction vessel in an argon atmosphere and cooled to a temperature of 0° C. in an ice-bath, and 7.0 mL of BF₃.Et₂O was added dropwise thereto. After the reaction mixture was stirred for 1 hour, 7.0 mL of BF₃.Et₂O was added thereto and further stirred for 1 hour. Then, the reaction mixture was stirred at room temperature for 5 hours. 100 mL of water was added thereto, and the mixture was stirred and transferred to a separatory funnel. Then, an organic layer was extracted therefrom three times by using 50 mL of chloroform. The extracted organic layer was dried by using sodium sulfate, and a solution was concentrated, and 30 mL of chloroform was added thereto. Crystals were obtained by adding 300 ml of methanol thereto while heating under reflux, and the obtained crystals were filtered. The crystals were added to 20 ml of chloroform and heated, and 200 ml of methanol was added thereto, and the mixture was stirred at room temperature for 2 hours. The generated crystals were filtered and dried to obtain 2.0 g of a solid (yield: 40%). The structure of the obtained Compound 3 was identified by ¹H-NMR.

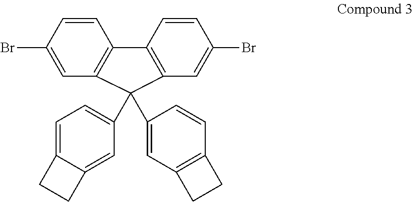 [SMILES: Brc1ccc2c(c1)C(c1ccc3c(c1)CC3)(c1ccc3c(c1)CC3)c1cc(Br)ccc1-2]

### Synthesis Example 4

### Synthesis of Compound 8

4-1. Synthesis of Compound 4

Compound 4 having the following structure was synthesized as follows. Specifically, 38.52 g (131.4 mmol) of 3-(4,4,5,5-tetramethyl-1,3,2-dioxaborane-2-yl)-9H-carbazole, 20.0 g (64.10 mmol) of 2,2′-dibromo-1,1′-biphenyl, 2.22 g (1.92 mmol) of tetrakis(triphenylphosphine)palladium(0) (Pd(PPh₃)₄), 39.86 g (288.46 mmol) of potassium cabonate, 144 mL of water, and 384 mL of 1,4-dioxane were added to a reaction vessel in an argon atmosphere, and the mixture was stirred at a temperature of 85° C. for 10 hours. After the reaction was completed, the reaction mixture was cooled to room temperature, and impurities were filtered and separated therefrom by using Celite (registered trademark). A solvent was distilled therefrom, methanol was added thereto, and a precipitated solid was filtered and removed therefrom. Methanol was added to a solid obtained therefrom, and the mixture was heated and stirred at a temperature of 80° C. for 2 hours. After the solid was filtered and removed therefrom, 100 mL of toluene and 400 mL of methanol were added thereto, and the solid was heated and stirred at a temperature of 80° C. for 2 hours. The solid was filtered and removed therefrom, and dried to obtain 20.7 g of Compound 4 (yield: 66%).

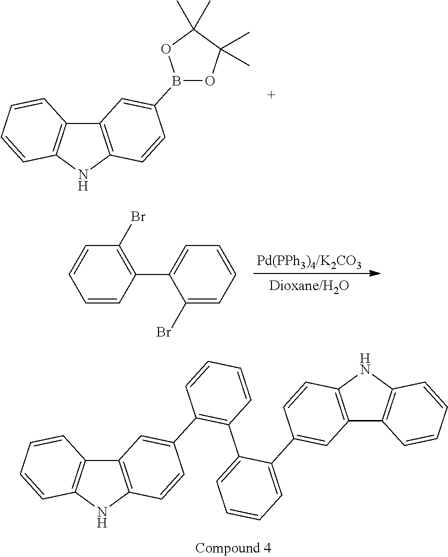 [SMILES: CC1(C)OB(c2ccc3[nH]c4ccccc4c3c2)OC1(C)C ; Brc1ccccc1-c1ccccc1Br ; c1ccc(-c2ccccc2-c2ccc3[nH]c4ccccc4c3c2)c(-c2ccc3[nH]c4ccccc4c3c2)c1]

4-2. Synthesis of Compound 5

9.70 g (20.0 mmol) of Compound 4, 9.89 g (41.03 mmol) of p-bromohexyl benzene, 7.68 g (80.08 mmol) of sodium tert-butoxide (t-BuONa), 20.408 g (0.80 mmol) of bis(tri-tert-butylphosphine)palladium (Pd(t-Bu₃P), and 200 mL of xylene were added to an argon-substituted three-neck flask, and the mixture was stirred for 4 hours under reflux. The reaction solution was cooled to room temperature, and impurities were filtered and removed from the reaction solution by using Celite (registered trademark). An organic layer was passed through an alumina column, and a solvent was distilled under reduced pressure. A solid obtained therefrom was recrystallized by toluene and hexane to obtain 10.0 g of Compound 5 (yield: 62%).

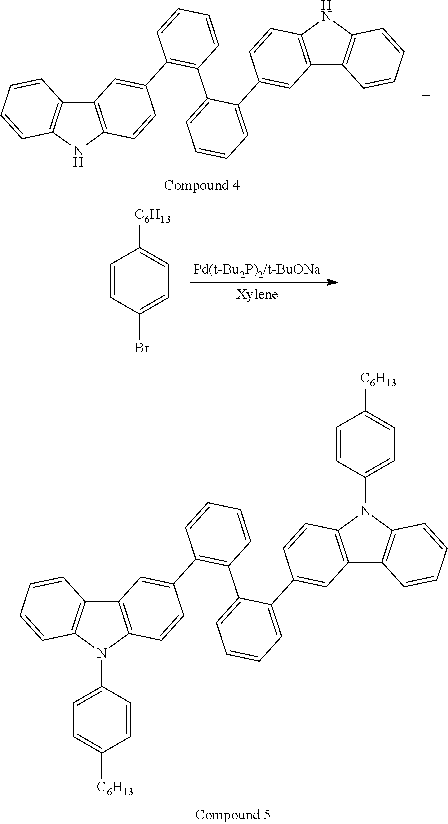

4-3. Synthesis of Compound 6

10.0 g (12.42 mmol) of Compound 5 and 100 mL of chloroform were added to a three-neck flask and cooled to a temperature of below −5° C. A solution in which 4.53 g (25.46 mmol) of N-bromosuccinimide (NBS) was dissolved in 10 mL of dimethyl formamide was stirred for 2 hours while the internal temperature was kept below 0° C. Water was added to the reaction solution, extraction was performed thereon by using chloroform, and drying was performed thereon by using magnesium sulfate. A solvent was distilled from the extraction solution under reduced pressure, and a residue was recrystallized by a mixed solvent including toluene and hexane and purified to obtain 11.2 g of Compound 6 (yield: 93%).

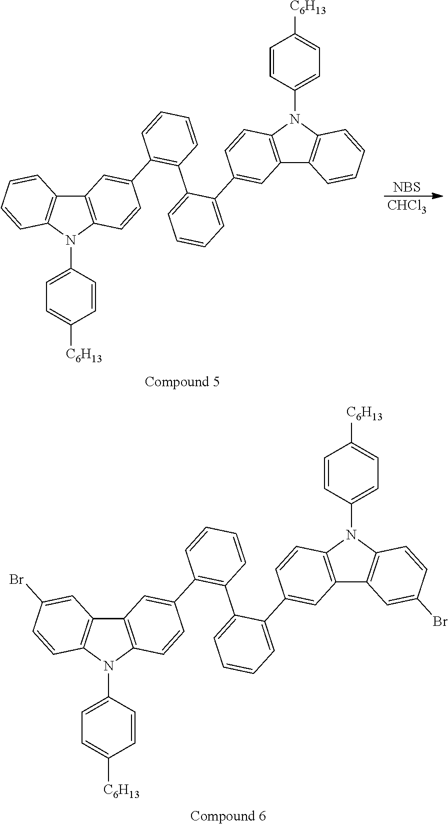

4-4. Synthesis of Compound 7

11.0 g (11.42 mmol) of Compound 6, 4.29 g (23.42 mmol) of 4-methyl diphenylamine, 6.58 g (68.53 mmol) of sodium tert-butoxide, 0.24 g (0.46 mmol) of bis(tri-tert-butylphosphine)palladium (Pd(t-Bu₃P)₂, and 200 mL of xylene were added to an argon-substituted three-neck flask. The mixture was refluxed for 3 hours, and cooled to room temperature. Impurities were filtered and removed from the cooled reaction solution by using Celite (registered trademark). An organic layer was passed through an alumina column, and a solvent was distilled from an eluent under reduced pressure. A residue obtained therefrom was recrystallized by a mixed solvent including toluene and hexane to obtain and purified to obtain 13.0 g of Compound 7 (yield: 97%).

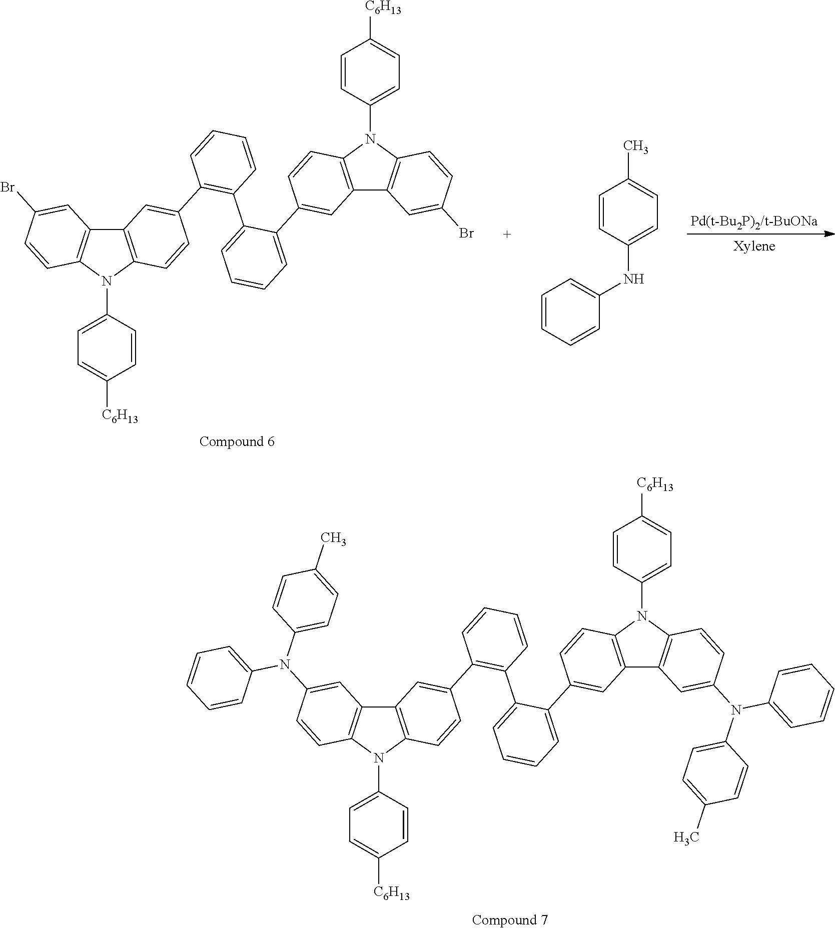

4-5. Synthesis of Compound 8

12.5 g (10.70 mmol) of Compound 7 and 150 mL of chloroform were added to an argon-substituted three-neck flask and cooled to a temperature of below −5° C. A solution in which 3.85 g (21.93 mmol) of N-bromosuccinimide (NBS) was dissolved in 15 mL of dimethyl formamide was stirred for 2 hours while the internal temperature was kept below 0° C. The reaction solution was poured into 300 mL of methanol to filter and remove a precipitated solid. Methanol was added to the solid, and the mixture was heated and stirred at a temperature of 80° C. for 1 hour. After the solid was filtered and removed therefrom, recrystallization was performed thereon three times by using a mixed solvent including chloroform and iso-propyl alcohol and purified to obtain 12.2 g of Compound 8 (yield: 86%).

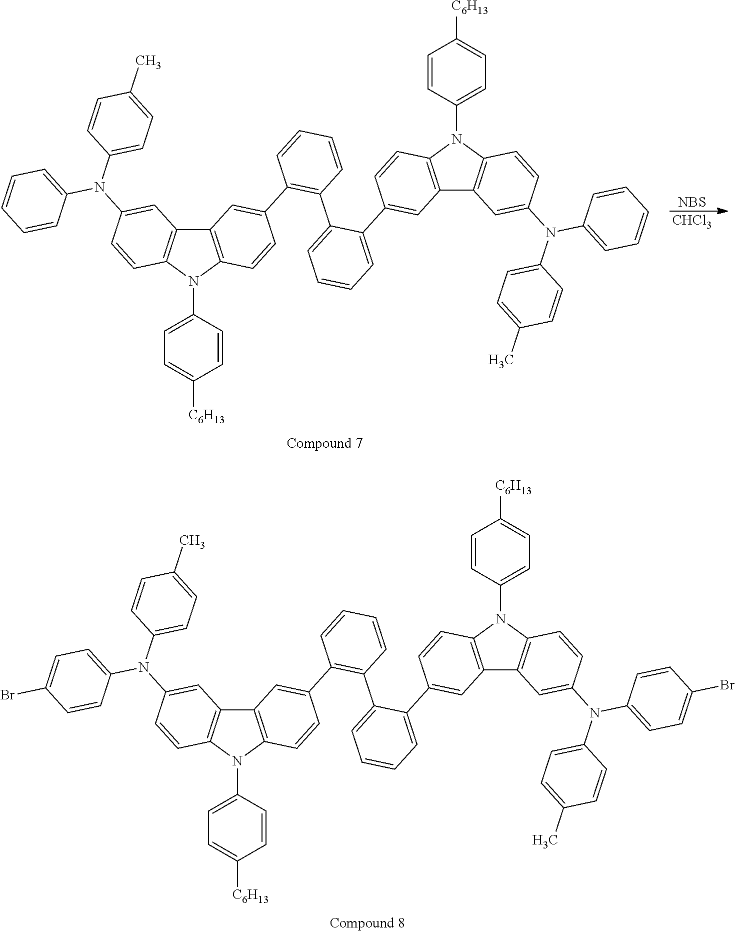

### Synthesis Example 5

### Synthesis of Compound 17

5-1. Synthesis of Compound 9

25.0 g (89.60 mmol) of 2-iodine-4-methoxy-1-nitrobenzene, 18.89 g (94.08 mmol) of 2-bromophenylboronic acid, 2.07 g (1.79 mmol) of tetrakis(triphenylphosphine)palladium(0) [Pd(PPh₃)₄], 28.48 g (268.79 mmol) of sodium carbonate, 134 ml of water, 131 mL of dimethoxyether (DME), 131 mL of toluene were added to a reactor in an argon atmosphere, and the mixture was stirred at a temperature of 85° C. for 15 hours. After the reaction was completed, the reaction mixture was cooled to room temperature, and impurities were filtered and separated therefrom by using Celite (registered trademark). After water was added to a filtrate, an organic layer was extracted therefrom by using toluene, and the extracted organic layer was concentrated. A concentrated solution was purified by column chromatography 22.0 g of Compound 9 (yield: 79%).

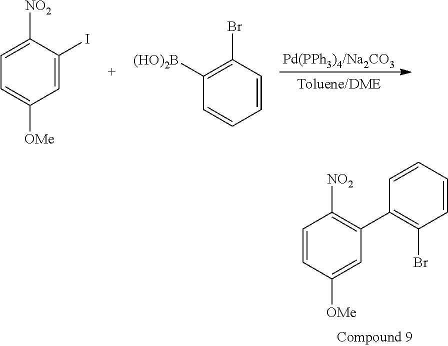 [SMILES: COc1ccc([N+](=O)[O-])c(I)c1 ; OB(O)c1ccccc1Br ; COc1ccc([N+](=O)[O-])c(-c2ccccc2Br)c1]

5-2. Synthesis of Compound 10

20.00 g (64.94 mmol) of Compound 9, 42.56 g (162.27 mmol) of triphenylphosphine (PPh₃), and 136 mL of o-dichlorobenzene were added to a nitrogen-substituted three-neck flask and refluxed at a temperature of 180° C. for 20 hours. A solvent was distilled under reduced pressure, and a residue obtained therefrom was purified by column chromatography charged with silica gel to obtain 9.60 g of Compound 10 (yield: 53%).

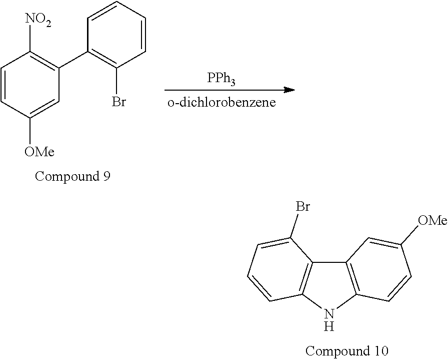 [SMILES: COc1ccc([N+](=O)[O-])c(-c2ccccc2Br)c1 ; COc1ccc2[nH]c3cccc(Br)c3c2c1 ; "PPh3"]

5-3. Synthesis of Compound 11

In an argon atmosphere, 500 mL of dehydrated 1,4-dioxane was added to 5.48 g (20.0 mmol) of p-iodinepentylbenzene, 5.00 g (18.1 mmol) of Compound 10, 0.19 g (1.0 mmol) of copper iodide, and 2.51 g (26.18 mmol) of sodium tert-butoxide, and the mixture was stirred at room temperature for 30 minutes. Then, 0.53 g (4.65 mmol) of trans-1,2-cyclohexanediamine (DACyHx) was added thereto, and the mixture was stirred for 8 hours under reflux.

After the reaction was completed, the mixture was cooled to room temperature and passed through Celite (registered trademark). A filtrate obtained therefrom was concentrated. A concentrated residue was purified by silica gel column chromatography to obtain 5.35 g of a white solid (yield: 70%).

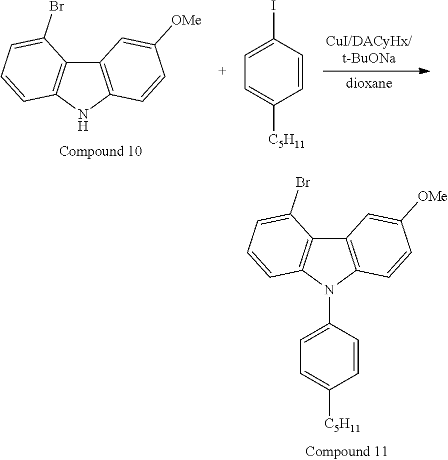

5-4. Synthesis of Compound 12

13.40 g (31.73 mmol) of Compound 11 was added to an argon-substituted three-neck flask, and 190 mL of tetrahydrofuran (THF) was added and dissolved. The mixture was cooled to a temperature of −75° C. by using an acetone/dry ice bath and stirred for 15 minutes. Then, 13.17 mL (34.90 mmol) of 2.6 M hexane solution of n-butyl lithium (n-BuLi) was added dropwise thereto, and the mixture was stirred for 1 hour. Then, 7.07 ml (34.90 mmol) of 2-iso-propoxy-4,4,5,5-tetramethyl-1,3,2-dioxaborolane was added thereto, and the mixture was stirred at room temperature for 3 hours. After the reaction was completed, water was added to the reaction mixture, and an organic layer was extracted therefrom by using ethyl acetate. Then, the extracted organic layer was concentrated to obtain a solid. The obtained solid was purified through recrystallization by hexane to obtain 10.0 g of Compound 12 (yield: 67%).

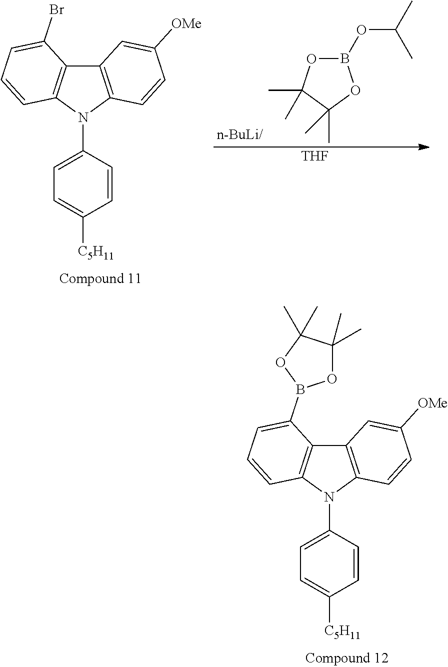

5-5. Synthesis of Compound 13

8.0 g (17.0 mmol) of Compound 12, 2.5 g (8.0 mmol) of 2,2′-dibromo-1,1′-biphenyl, 0.19 (0.17 mmol) of tetrakis(triphenylphosphine)palladium(0) (Pd(PPh₃)₄), 1.86 g (17.6 mmol) of sodium carbonate, 20 mL of water, and 50 mL of 1,4-dioxane were stirred at a temperature of 85° C. for 10 hours in a reactor in an argon atmosphere. After the reaction was completed, the reaction mixture was cooled to room temperature, and impurities were filtered and separated therefrom by using Celite (registered trademark). After a solvent was distilled, methanol was added thereto and a precipitated solid was filtered and separated therefrom. Methanol was added to a solid obtained therefrom and heated at a temperature of 80° C. for 2 hours under reflux. The solid was filtered and removed therefrom by adding toluene and methanol thereto, and dried to obtain 4.0 g of Compound 13 (yield: 60%).

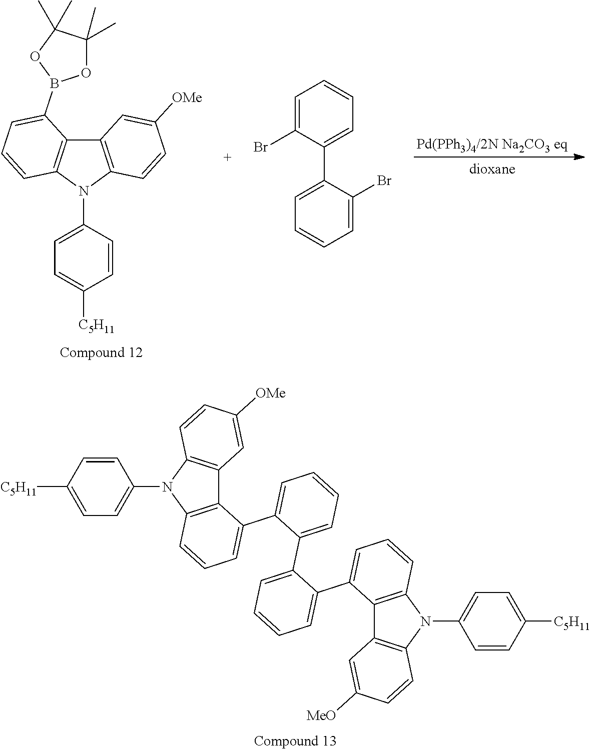

5-6. Synthesis of Compound 14

A reaction solution in which 4.0 g (4.7 mmol) of Compound 13 was added to 50 mL of dichloromethane was stirred at a temperature of 0° C. in an argon atmosphere. Then, a dichloromethane solution including boron tribromide (10.34 mmol) was added dropwise thereto, and the mixture was stirred at room temperature for 18 hours. The reaction mixture was cooled to a temperature of 0° C., and 40 mL of water was added thereto to separate an organic layer. A solvent was distilled under reduced pressure. A residue obtained therefrom was purified by silica gel column chromatography (developing solvent: toluene) to obtain 3.7 g of Intermediate (OH type) (yield: 99%).

Then, 3.7 g (4.5 mmol) of Intermediate (OH type), 1.1 g (10.73 mmol) of 2,6-lutidine, and 150 mL of dehydrated dichloromethane were added in an argon atmosphere and cooled to a temperature of 0° C. in an ice bath. Then, 3.0 g (10.80 mmol) of trifluoromethanesulfonic anhydride (Tf₂O) was added thereto and reacted at room temperature for 5 hours.

After the reaction was completed, 150 mL of water was added thereto to extract an organic layer. The extracted organic layer was dried by using magnesium sulfate and filtrated to remove magnesium sulfate. A solvent was removed under reduced pressure, and a residue obtained therefrom was separated by silica gel column chromatography to obtain 3.8 g of Compound 14 (yield: 80%).

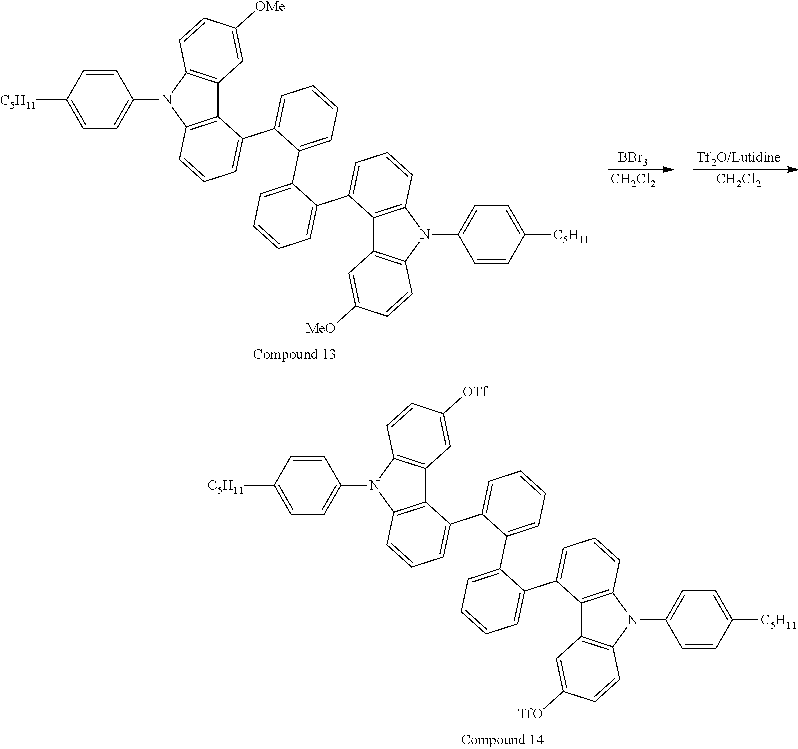

5-7. Synthesis of Compound 15

3.8 g (3.6 mmol) of Compound 14, 0.77 g (7.2 mmol) of 4-methylamine, and 50 mL of dehydrated toluene were added to a flask in an argon atmosphere, and the mixture was stirred at room temperature for 30 minutes. Then, 92 mg (0.10 mmol) of tris(dibenzylideneacetone)dipalladium, 221 mg (0.40 mmol) of 1,1′-bis(diphenylphosphino)ferrocene, and 1.3 g (14.4 mmol) of sodium t-butoxide were added thereto, and the mixture was stirred at a temperature of 95° C. for 2 hours. The reaction mixture was cooled to room temperature, and water and toluene were added thereto to perform liquid separation and washing. An organic layer obtained therefrom was dried by using magnesium sulfate, dried, filtered, and then concentrated. A residue obtained therefrom was purified by column chromatography (developing solvent: hexane/ethyl acetate=95/5) to obtain 2.1 g of Compound 15 (yield: 60%).

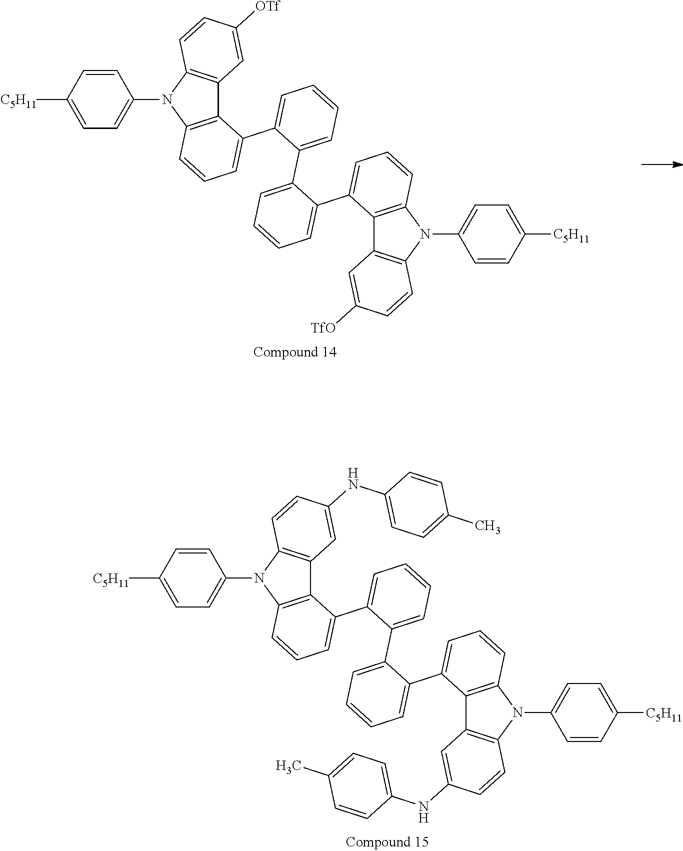

5-8. Synthesis of Compound 16

150 mL of dehydrated 1,4-dioxane was added to 1.27 g (4.5 mmol) of p-bromoiodine benzene, 2.1 g (2.1 mmol) of Compound 15, 0.043 g (0.23 mmol) of copper iodide, and 0.56 g (5.89 mmol) of sodium tert-butoxide in an argon atmosphere, and the mixture was stirred at room temperature for 30 minutes. Then, 0.115 g (1.04 mmol) of tris-1,2-cyclohexane diamine was added thereto, and the mixture was heated and stirred for 8 hours under reflux.

After the reaction was completed, the reaction mixture was cooled to room temperature and passed through Celite (registered trademark), and a filtrate was concentrated. A concentrated residue obtained therefrom was purified by silica gel column chromatography to obtain 1.36 g of Compound 16 (yield: 50%).

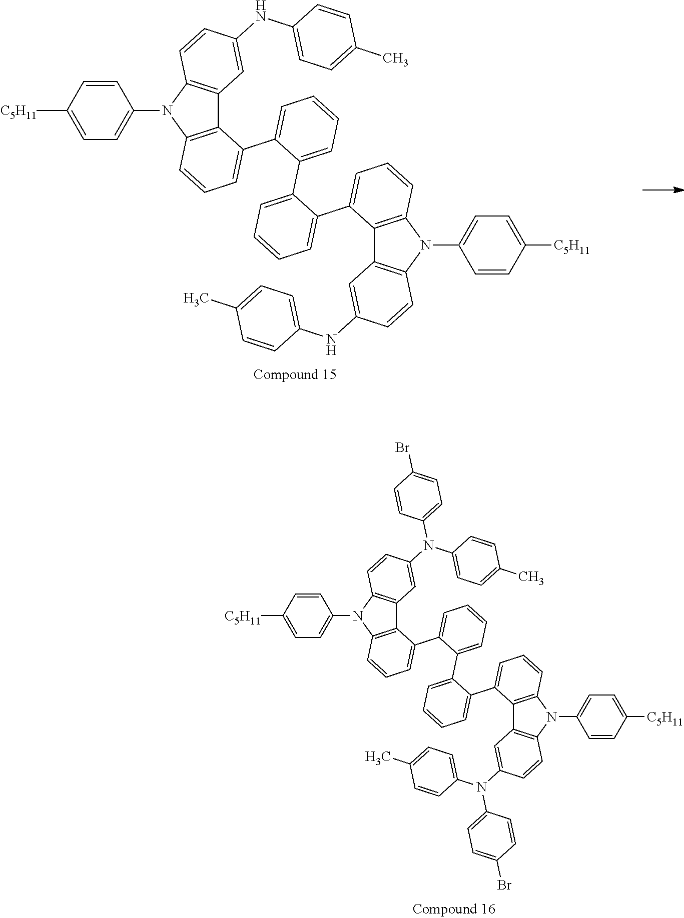

### Synthesis Example 5

### Synthesis of Compound 17

5.2 g (17.0 mmol) of boronic ester, 2.5 g (8.0 mmol) of 2,2′-dibromo-1,1′-biphenyl, 0.19 g (0.17 mmol) of tetrakis(triphenylphosphine)palladium(0) (Pd(PPh₃)₄), 1.86 g (17.6 mmol) of sodium carbonate, 20 mL of water, and 50 mL of 1,4-dioxane were added to a reactor in an argon atmosphere, and the reaction mixture was stirred at a temperature of 85° C. for 10 hours. The reaction was completed, the reaction mixture was cooled to room temperature and impurities were filtered and separated by using Celite (registered trademark). After a solvent was distilled, methanol was added thereto, and a precipitated solid was filtered and removed therefrom. Methanol was added to a solid obtained therefrom, and the mixture was heated and stirred at a temperature of 80° C. for 2 hours. The solid was filtered and removed therefrom by adding toluene and methanol and dried to obtain 6.4 g of Compound 17 (yield: 73%).

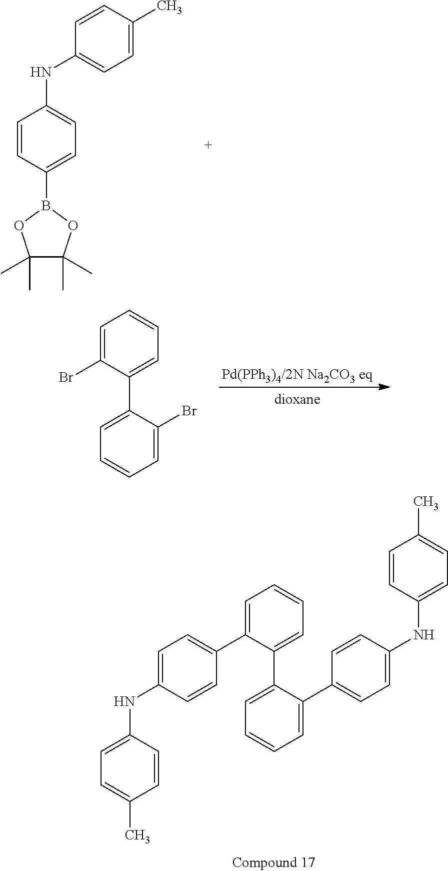

### Synthesis Example 6

### Synthesis of Compound 19

6-1. Synthesis of Compound 18

3.34 g (20.0 mmol) of 9H-carbazole, 9.62 g (20.50 mmol) of 2-bromo-9,9-dioctylfluorene, 3.84 g (40.04 mmol) of sodium-tert-butoxide (t-BuONa), 0.204 g (0.40 mmol) of bis(tri-tert-butylphosphine)palladium (Pd(t-Bu₃P)₂, and 100 mL of xylene were added to an argon-substituted three-neck flask, and the mixture was stirred for 4 hours under reflux. The reaction solution was cooled to room temperature and impurities were filtered and separated therefrom by using Celite (registered trademark). An organic layer obtained therefrom passed through an alumina column, and a solvent was distilled from an eluent under reduced pressure to obtain 8.3 g of Compound 18 (yield: 75%).

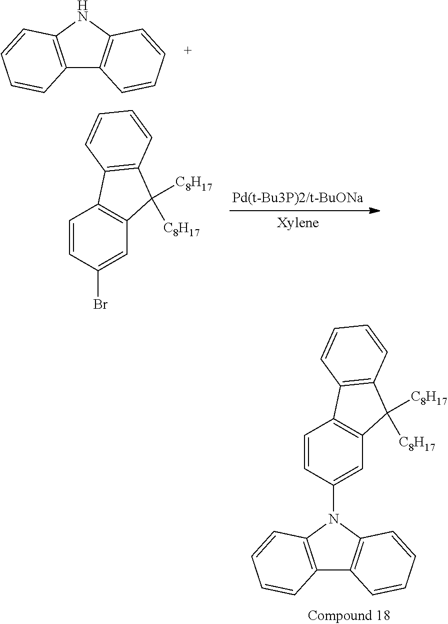

6-2. Synthesis of Compound 19

8.0 g (14.37 mmol) of Compound 18 and 150 mL of chloroform were added to an argon-substituted three-neck flask and cooled to below −5° C. A solution in which 5.6 g (31.66 mmol) of N-bromosuccinimide (NBS) was dissolved in 25 mL of dimethylformamide was stirred for 2 hours while the internal temperature was kept below 0° C. After the reaction was completed, liquid separation was performed thereon by adding 300 mL of water thereto. An organic layer obtained therefrom was dried by using sodium sulfate and purified by silica gel column chromatography to obtain 8.8 g of Compound 19 (yield: 86%).

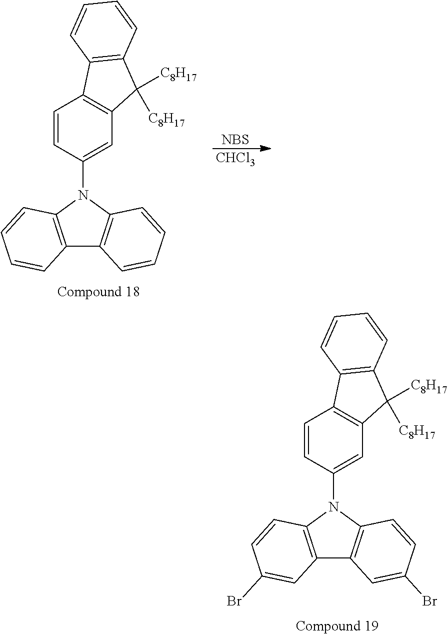

### Example 1

### Synthesis of Polymer Compound A-1

Polymer Compound A-1 including the following repeating unit A and repeating unit B was synthesized by using Compound 1, Compound 2, Compound 3, and Compound 8, which were synthesized in Synthesis Examples.

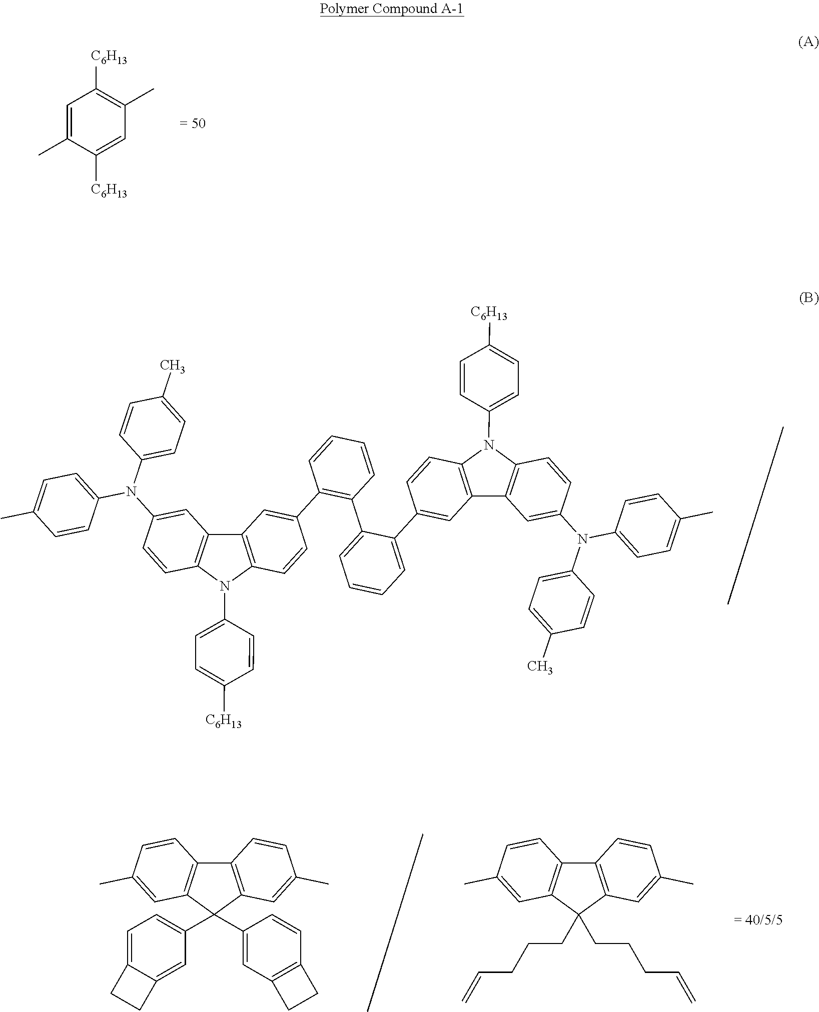

1.49 g (3.0 mmol) of Compound 1, 0.138 g (0.30 mmol) of Compound 2, 0.159 g (0.30 mmol) of Compound 3, 3.22 g (2.4 mmol) of Compound 8, 2.15 mg of palladium acetate, 20.25 mg of tris(2-methoxyphenyl)phosphine, 45 mL of toluene, and 11.42 g of 20 wt % tetraethylammonium hydroxide aqueous solution were stirred for 7 hours in an argon atmosphere. Then, 23.30 mg (0.57 mmol) of phenylboronic acid, 2.15 mg of palladium acetate, 10.12 mg of tris(2-methoxyphenyl)phosphine, and 11.42 g of 20 wt % tetraethylammonium hydroxide aqueous solution were heated for 7 hours under reflux. Then, a water layer was removed, 5.4 g (23.97 mmol) of N,N-diethyldithiocarbamate sodium trihydrate and 50 mL of ion-exchange water were added thereto and additionally stirred at a temperature of 85° C. for 2 hours. After an organic layer was separated from the water layer, the organic layer was sequentially washed with water, 3 wt % of acetic acid aqueous solution, and water. The organic layer was added dropwise to methanol, and a polymer compound was precipitated, filtered and dried to obtain a solid. The solid was dissolved in toluene and passed through column chromatography charged with silica gel and alumina, and a solvent was distilled under reduced pressure. A liquid obtained therefrom was added dropwise to methanol, and a precipitated solid was filtered, separated, and dried to obtain Polymer Compound A-1.

From the addition ratio of the monomers, it was estimated that the obtained Polymer Compound A-1 was a polymer compound in which the repeating unit A having the above composition (the repeating unit derived from Compound 1: the repeating unit derived from Compound 8: the repeating unit derived from Compound 3: the repeating unit derived from Compound 2 was 50:40:5:5 (molar ratio)) and the repeating unit B were alternately polymerized. Also, it was estimated by size exclusion chromatography (SEC) that the number average molecular weight (Mn) and the molecular weight distribution (Mw/Mn) of Polymer Compound A-1 were Mn=55,000 and Mw/Mn=2.54.

### Example 2

### Synthesis of Polymer Compound A-2

Polymer Compound A-2 including the following repeating unit A′ and repeating unit B′ was synthesized by using Compound 1, Compound 2, Compound 3, and Compound 16, which were synthesized in Synthesis Examples.

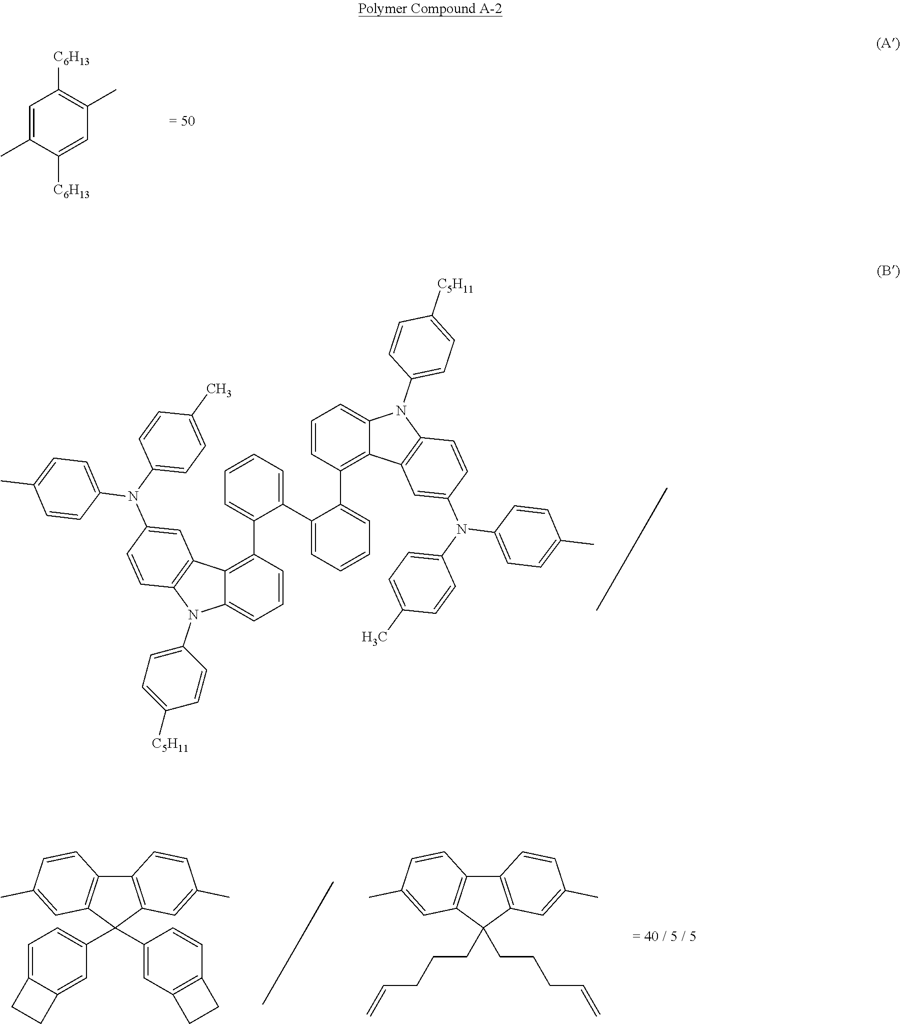

1.49 g (3.0 mmol) of Compound 1, 0.138 g (0.30 mmol) of Compound 2, 0.159 g (0.30 mmol) of Compound 3, 3.12 g (2.4 mmol) of Compound 16, 2.15 mg of palladium acetate, 20.25 mg of tris(2-methoxyphenyl)phosphine, 45 mL of toluene, and 11.42 g of 20 wt % tetraethylammonium hydroxide aqueous solution were stirred for 7 hours in an argon atmosphere. Then, 23.30 mg (0.57 mmol) of phenylboronic acid, 2.15 mg of palladium acetate, 10.12 mg of tris(2-methoxyphenyl)phosphine, and 11.42 g of 20 wt % tetraethylammonium hydroxide aqueous solution were heated for 7 hours under reflux. Then, a water layer was removed, 5.4 g (23.97 mmol) of N,N-diethyldithiocarbamate sodium trihydrate and 50 mL of ion-exchange water were added thereto and additionally stirred at a temperature of 85° C. for 2 hours. After an organic layer was separated from the water layer, the organic layer was sequentially washed with water, 3 wt % of acetic acid aqueous solution, and water. The organic layer was added dropwise to methanol, and a polymer compound was precipitated, filtered and dried to obtain a solid. The solid was dissolved in toluene and passed through column chromatography charged with silica gel and alumina, and a solvent was distilled under reduced pressure. A liquid obtained therefrom was added dropwise to methanol, and a precipitated solid was filtered, separated, and dried to obtain Polymer Compound A-2.

From the addition ratio of the monomers, it was estimated that the obtained Polymer Compound A-2 was a polymer compound in which the repeating unit A′ having the composition (the repeating unit derived from Compound 1: the constituent unit derived from Compound 16: the repeating unit derived from Compound 3: the repeating unit derived from Compound 2 was 50:40:5:5 (molar ratio)) and the repeating unit B′ were alternately polymerized. Also, it was estimated by SEC that the number average molecular weight (Mn) and the molecular weight distribution (Mw/Mn) of Polymer Compound A-2 were Mn=40,000 and Mw/Mn=2.50.

### Example 3

### Synthesis of Polymer Compound A-3

Polymer Compound A-3 including the following repeating unit A″ and repeating unit B″ was synthesized by using Compound 17, Compound 2, Compound 3, and Compound 19, which were synthesized in Synthesis Examples.

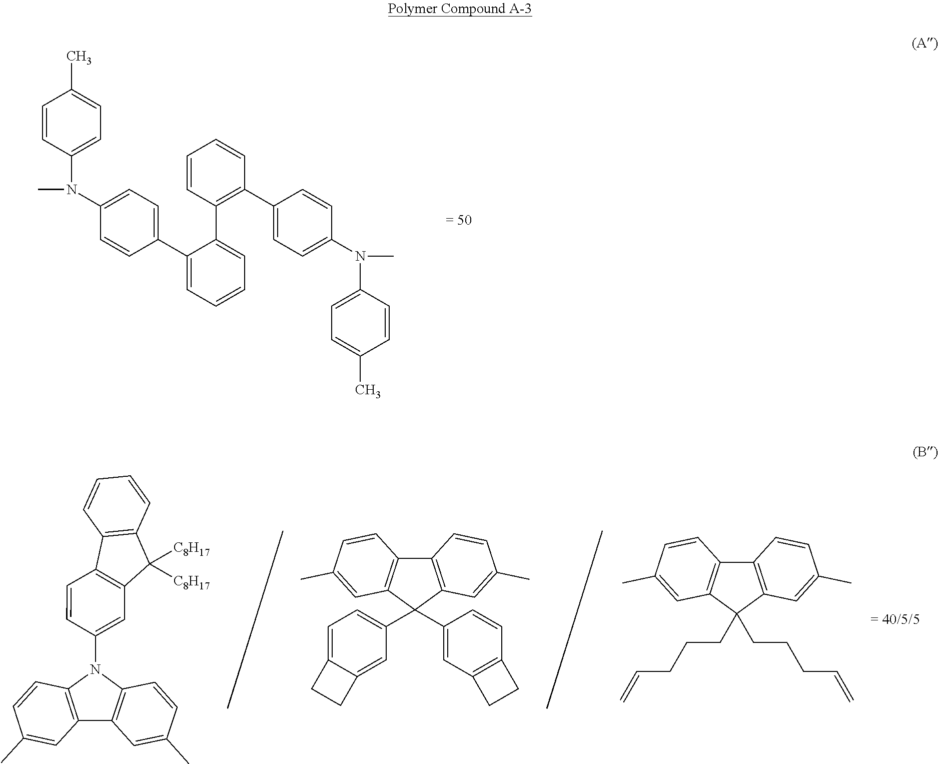

4.00 g (7.74 mmol) of Compound 17, 0.35 g (0.774 mmol) of Compound 2, 0.41 g (0.774 mmol) of Compound 3, 4.22 g (5.92 mmol) of Compound 19, and 55 mL of toluene were stirred at a temperature of 60° C. for 3 minutes in an argon atmosphere.

Then, 0.14 g (0.16 mmol) of tris(dibenzylidene acetone)dipalladium and 0.32 g (1.20 mmol) of 4-(N,N-dimethylamino)phenyl]di-tert-butylphosphine (Amphos) were added thereto and heated for 2 hours under reflux. After confirming that disappearance of each monomer, 0.89 g (0.56 mmol) of bromobenzene was added thereto and heated for 2 hours under reflux. After the reaction was completed, the reaction solution was cooled to room temperature, and 50 mL of toluene was added thereto. Then, the reaction solution was added dropwise to 500 mL of methanol to obtain a solid.

The solid was dissolved in toluene and passed through column chromatography charged with silica gel and alumina to distill the solvent under reduced pressure. A liquid obtained therefrom was added dropwise to methanol, and a precipitated solid was filtered, separated, and dried to obtain Polymer Compound A-3.

From the addition ratio of the monomers, it was estimated that the obtained Polymer Compound A-3 was a polymer compound in which the repeating unit A″ having the composition (the repeating unit derived from Compound 17: the constituent unit derived from Compound 19: the repeating unit derived from Compound 3: the repeating unit derived from Compound 2 was 50:40:5:5 (molar ratio)) and the repeating unit B″ were alternately polymerized. Also, it was estimated by SEC that the number average molecular weight (Mn) and the molecular weight distribution (Mw/Mn) of Polymer Compound A-3 were Mn=9,100 and Mw/Mn=1.64.

Mn=9,100, Mw/Mn=1.64.

The triplet energy levels (eV) of Polymer Compounds A-1 to A-3 prepared according to Examples 1 to 3 and poly[(9,9-dioctylfluorenyl-2,7-diyl)-co-(4,4′-(N-(4-sec-butyl phenyl) diphenylamine) (TFB) (product of Luminescence Technology Corp.) having the following repeating unit (Comparative Example 1) were measured according to the following method. Results thereof are shown in Table 1.

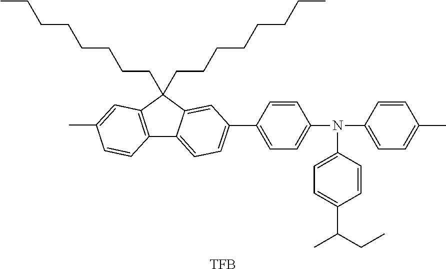

### Evaluation Example 1

### Measurement of Triplet Energy Level

A coating solution was prepared by dissolving each Compound in toluene such that the concentration thereof was 3.2 wt %. The coating solution was spin-coated at a rotating speed of 1,600 revolutions per minute (rpm) and dried at a temperature of 250° C. for 60 minutes on a hot plate to obtain a film (sample) having a thickness of about 70 nanometers (nm) (thickness after drying). The sample was cooled to 77 Kelvins (K) (−196° C.) and a photoluminescence (PL) spectrum was measured. Also, the triplet energy level (electron volts, eV) was calculated from the peak value of the shortest wave side of the PL spectrum, and results thereof are shown in Table 1.

TABLE 1

| | Polymer | Mn | Mw | Triplet energy |
|---|---|---|---|---|
| | Compound | (×104) | (×104) | level (eV) |
| Example 1 | A-1 | 5.5 | 14.0 | 2.70 |
| Example 2 | A-2 | 4.0 | 10.0 | 2.75 |
| Example 3 | A-3 | 0.9 | 1.5 | 2.42 |
| Comparative | TFB | 8.6 | 18.3 | 2.30 |
| Example 1 | | | | |

From the results of Table 1, it is confirmed that the polymer compounds have a significantly high triplet energy level, as compared with TFB that is an existing polymer compound.

### Example 4

### Manufacture of Organic Light-Emitting Device Device-1

As a first electrode (anode), a hole injection layer was formed on an ITO glass substrate, on which stripe-shaped indium tin oxide (ITO) was deposited to a film thickness of 150 nm, by spin coating, such that PEDOT/PSS (product of Sigma-Aldrich) had a dry film thickness of 30 nm.

Then, Polymer Compound A-1 (hole transport material A-1) synthesized in Example 1 was dissolved in xylene (solvent) at a concentration of 1 wt % to prepare a coating liquid for forming a hole transport layer. The coating liquid (A-1) for forming a hole transport layer was applied on the hole injection layer by spin coating, such that a thickness (dry film thickness) was 30 nm, and heat treatment was performed thereon at a temperature of 230° C. for 1 hour to form a hole transport layer having a thickness (dry film thickness) of 30 nm.

Also, prepared was a toluene solution including Compound h-1 (6,9-diphenyl-9′-(5′-phenyl-[1,1′:3′,1″-terphenyl]-3-yl)3,3′-bis[9H-carbazole) and Compound h-2 (3,9-diphenyl-5-(3-(4-phenyl-6-(5′-phenyl-[1,1′:3′,1″-terphenyl]-3-yl)-1,3,5-triazine-2-yl)ph enyl)-9H-carbazole) as a host material, and tris(2-(3-p-xylyl)phenyl)pyridine iridium(III) as a dopant material on the hole transport layer. At this time, the toluene solution was prepared so that Compound h-1 has a concentration of 0.49 grams per milliliter (g/mL) and Compound h-2 has a concentration of 0.05 g/mL. Also, an amount of the dopant material was adjusted so that a doping amount was 10 percent by weight (wt %) based on the total weight of the emission layer. The toluene solution was applied on the hole transport layer to a dry film thickness of 30 nm by spin coating, thereby forming an emission layer.

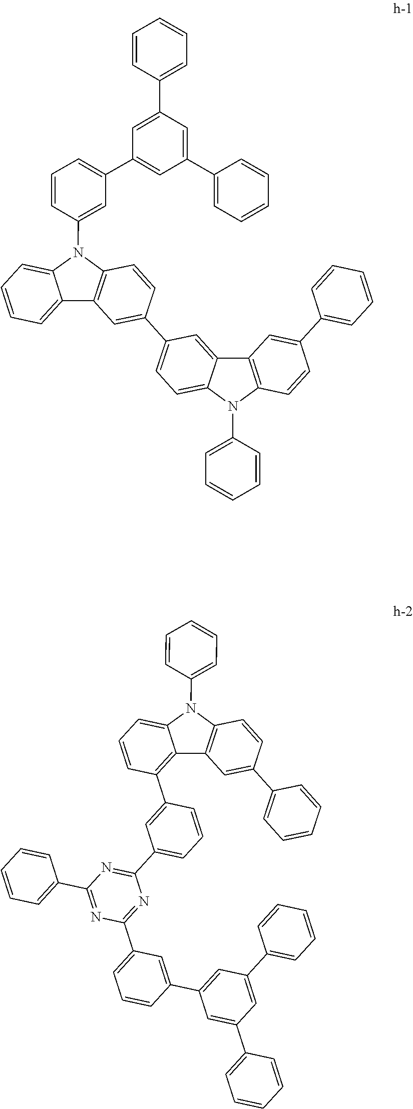 [SMILES: c1ccc(-c2cc(-c3ccccc3)cc(-c3cccc(-n4c5ccccc5c5cc(-c6ccc7c(c6)c6cc(-c8ccccc8)ccc6n7-c6ccccc6)ccc54)c3)c2)cc1 ; c1ccc(-c2cc(-c3ccccc3)cc(-c3cccc(-c4nc(-c5ccccc5)nc(-c5cccc(-c6cccc7c6c6cc(-c8ccccc8)ccc6n7-c6ccccc6)c5)n4)c3)c2)cc1]

Then, (8-quinolinolato)lithium (LiQ) and KLET-03 (product of Chemipro Kasei) were vacuum-deposited on the emission layer in a vacuum deposition apparatus to form an electron transport layer having a thickness of 50 nm. Also, lithium fluoride (LiF) was deposited on the electron transport layer in the vacuum deposition apparatus to form an electron injection layer having a thickness of 1 nm.

Then, aluminum was deposited on the electron injection layer in the vacuum deposition apparatus to form a second electrode (cathode) having a thickness of 100 nm. In this manner, the manufacture of an organic light-emitting device Device-1 was completed.

### Example 5

### Manufacture of Organic Light-Emitting Device Device-2

An organic light-emitting device Device-2 was manufactured in the same manner as in Example 4, except that Polymer Compound A-2 synthesized in Example 2 was used instead of Polymer Compound A-1.

### Example 6

### Manufacture of Organic Light-Emitting Device Device-3

An organic light-emitting device Device-3 was manufactured in the same manner as in Example 4, except that Polymer Compound A-3 (hole transport material A-3) synthesized in Example 3 was used instead of Polymer Compound A-1 (hole transport material A-1) in forming a hole transport layer.

### Comparative Example 2

### Manufacture of Organic Light-Emitting Device Device-4

An organic light-emitting device Device-4 was manufactured in the same manner as in Example 4, except that poly[(9,9-dioctylfluorenyl-2,7-diyl)-co-(4,4′-(N-(4-sec-butylphenyl) diphenylamine) (TFB) (product of Luminescence Technology Corp.) was used instead of Polymer Compound A-1 (hole transport material A-1) in forming a hole transport layer.

The current efficiency and durability (emission lifespan) of the organic light-emitting devices Device-1 to Device-3 manufactured according to Examples 4 to 6 and the organic light-emitting device Device-4 manufactured according to Comparative Example 2 were evaluated by using the following method. Results thereof are shown in Table 2.

### Evaluation Example 2

### Evaluation of Current Efficiency and Durability (Emission Lifespan)

First, when a predetermined voltage was applied to the organic light-emitting devices by using a DC constant voltage source (source meter, manufactured by KEYENCE), a current started to flow through the respective organic light-emitting devices at a constant voltage, and the organic light-emitting devices emitted light. The voltage at this time was set as a driving voltage (V). While the light emission of the organic light-emitting device was measured by using a luminance measurement apparatus (SR-3, manufactured by Topcom), a current applied to the organic light-emitting device was gradually increased. A current at which luminance reached 6,000 candelas per square meter (cd/m²) was constantly maintained.

A current density that was a current value per unit area of the organic light-emitting device was calculated, and current efficiency (candelas per ampere, cd/A) was calculated by dividing luminance (cd/m²) by the current density (amperes per square meter, A/m²).

The emission lifespan (hour, hr) indicates an amount of time that lapsed when luminance measured by the measurement apparatus was reduced to 95% of initial luminance (100%). Also, the current efficiency indicates efficiency (conversion efficiency) of converting a current into luminescence energy. As the current efficiency is higher, the organic light-emitting device has higher performance.

TABLE 2

| | Organic | | Current | Emission |
|---|---|---|---|---|
| | light-emitting | Hole transport | efficiency | lifespan |
| | device | material | (cd/A) | (time) |
| Example 4 | Device-1 | A-1 | 64 | 268 |
| Example 5 | Device-2 | A-2 | 70 | 122 |
| Example 6 | Device-3 | A-3 | 60 | 89 |
| Comparative | Device-4 | TFB | 20 | 10 |
| Example 2 | | | | |

Table 2, it is confirmed that the organic light-emitting devices Device-1 to Device-3 including the polymer compounds of Examples 1 to 3 as the hole transport material are excellent in terms of both current efficiency and emission lifespan, as compared with the organic light-emitting device Device-4 using an existing hole transport material (TFB). Therefore, it is confirmed that the polymer compounds may be suitably used as the light-emitting material, in particular, the hole transport material. Also, it is confirmed that the use of the polymer compounds of Examples enables a hole transport material to be formed by using coating, and thus mass production may be possible.

As described above, the polymer compound has a high triplet energy level and may enable a film to be easily formed by heating. Therefore, the use of the polymer compound may improve the thermal stability of the organic layer, thereby improving the emission lifespan of the organic light-emitting device.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present disclosure as defined by the following claims.

What is claimed is:

1. A polymer compound comprising:
a first repeating unit represented by Formula 1; and
a second repeating unit represented by Formula 3: 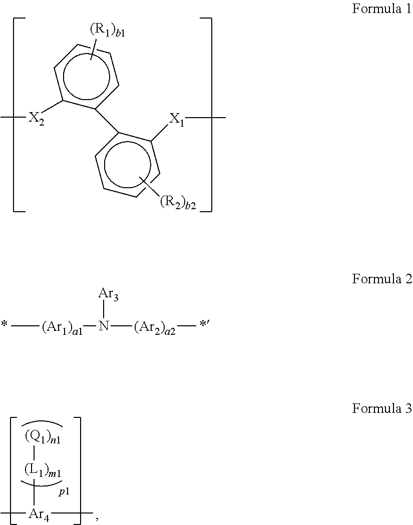
wherein, in Formula 1,
X₁ and X₂ are each independently represented by Formula 2,
R₁ and R₂ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,
b1 and b2 are each independently an integer from 1 to 4,
when b1 is two or more, two or more groups R₁ are identical to or different from each other, and
when b2 is two or more, two or more groups R₂ are identical to or different from each other,
wherein, in Formula 2,
Ar₁ to Ar₃ are each independently selected from a substituted or unsubstituted C₅-C₃₀ carbocyclic group and a substituted or unsubstituted C₁-C₃₀ heterocyclic group,
a1 and a2 are each independently an integer from 0 to 4,
provided that, when a1 is zero, Ar₁ is a single bond, and
when a2 is zero, Ar₂ is a single bond, and
* and *′ each indicate a binding site to a neighboring atom,
wherein, in Formula 3,
Ar₄ is a substituted or unsubstituted C₅-C₃₀ carbocyclic group or a substituted or unsubstituted C₁-C₃₀ heterocyclic group,
L₁ is selected from a single bond, a substituted or unsubstituted C₁-C₆₀ alkylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,
m1 is an integer from 0 to 5,
when m1 is zero, L₁ is a single bond,
when m1 is two or more, two or more groups L₁ are identical to or different from each other,
Q₁ is a monovalent crosslinking group comprising at least one selected from an ether group, a vinyl group, an acrylate group, a methacrylate group, a styryl group, an epoxy group, an oxetane group, and a benzocyclobutene group,
n1 is an integer from 1 to 5,
when n1 is two or more, two or more groups Q₁ are identical to or different from each other, and
p1 is an integer from 1 to 5, wherein, when p1 is two or more, two or more groups -(L₁)ₘ₁-(Q₁)ₙ₁ are identical to or different from each other.

2. The polymer compound of claim 1, wherein,
in the polymer compound, a1+a2≥1 is satisfied in Formula 2.

3. The polymer compound of claim 1, wherein
Ar₁ and Ar₂ in Formula 2 are each independently a substituent represented by one of Formulae A-1 to A-9: 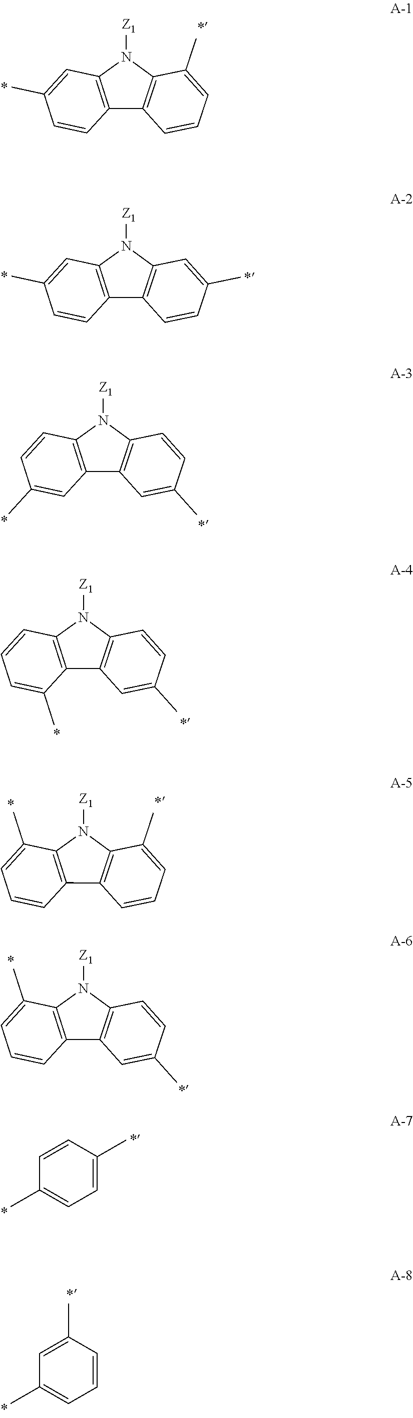 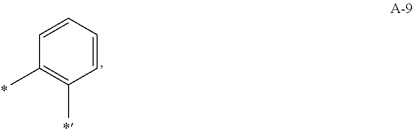
wherein, in Formulae A-1 to A-9,
Z₁ is selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and
* and *′ each indicate a binding site to a neighboring atom.

4. The polymer compound of claim 1, wherein
Ar₃ in Formula 2 is a substituent represented by one of Formulae B-1 to B-7: 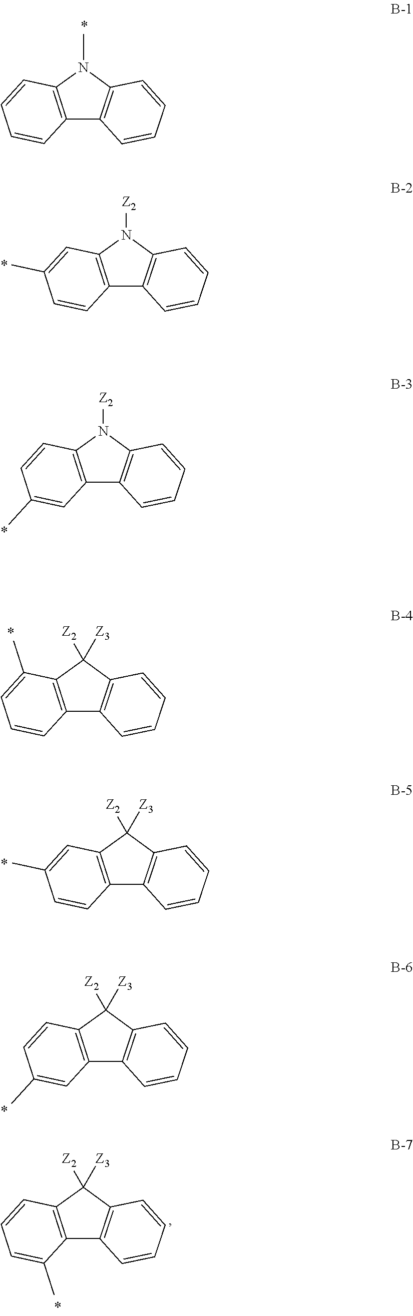
wherein, in Formulae B-1 to B-7,
Z₂ and Z₃ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, and
* indicates a binding site to a neighboring atom.

5. The polymer compound of claim 1, wherein
R₁ and R₂ are each independently selected from hydrogen, deuterium, —F, —Cl, —Br, —I, a hydroxyl group, a C₁-C₂₀ alkyl group, a C₁-C₂₀ alkoxy group, a phenyl group, a naphthyl group, a fluorenyl group, a spiro-bifluorenyl group, a triphenylenyl group, a biphenyl group, a dimethylfluorenyl group, a diphenylfluorenyl group, and a carbazolyl group.

6. The polymer compound of claim 1, wherein
the first repeating unit is represented by one of Formulae 1-1 to 1-10: 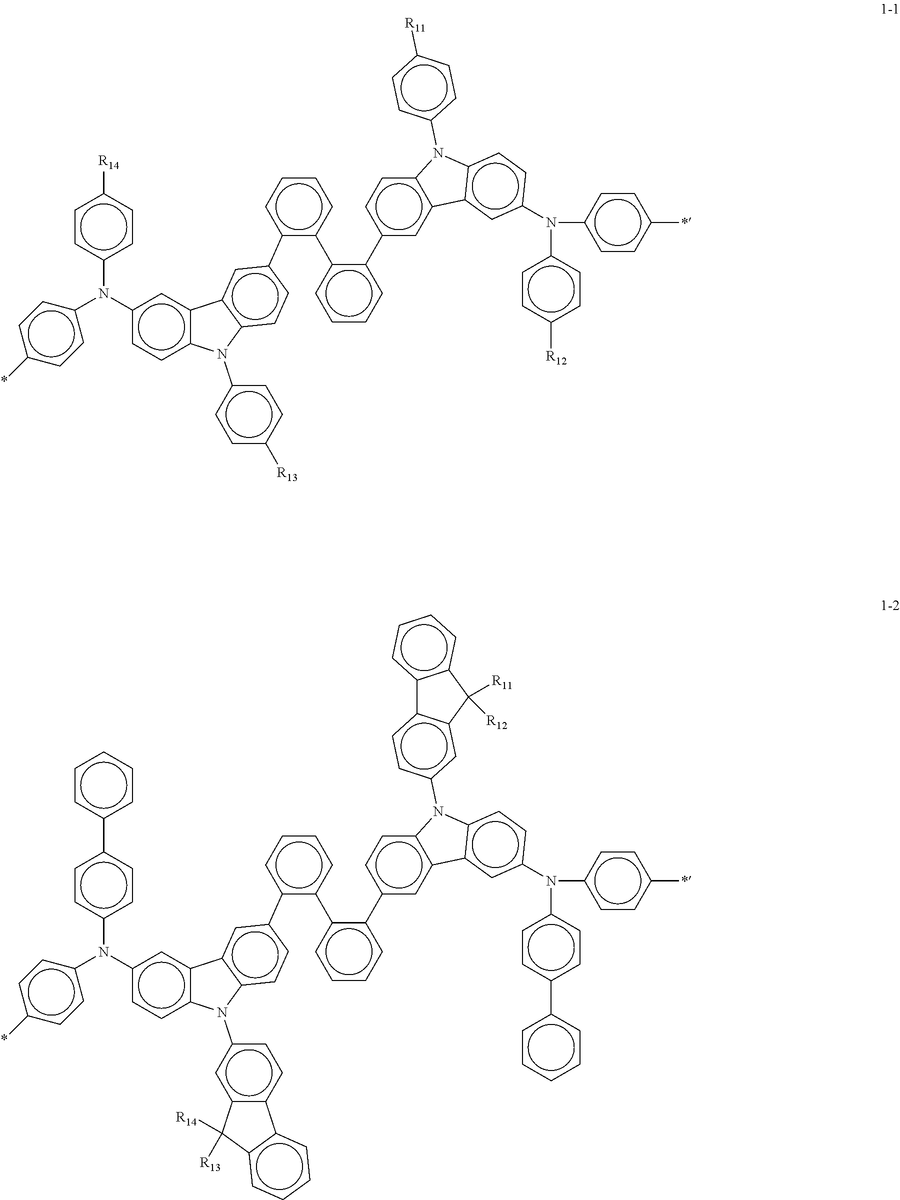 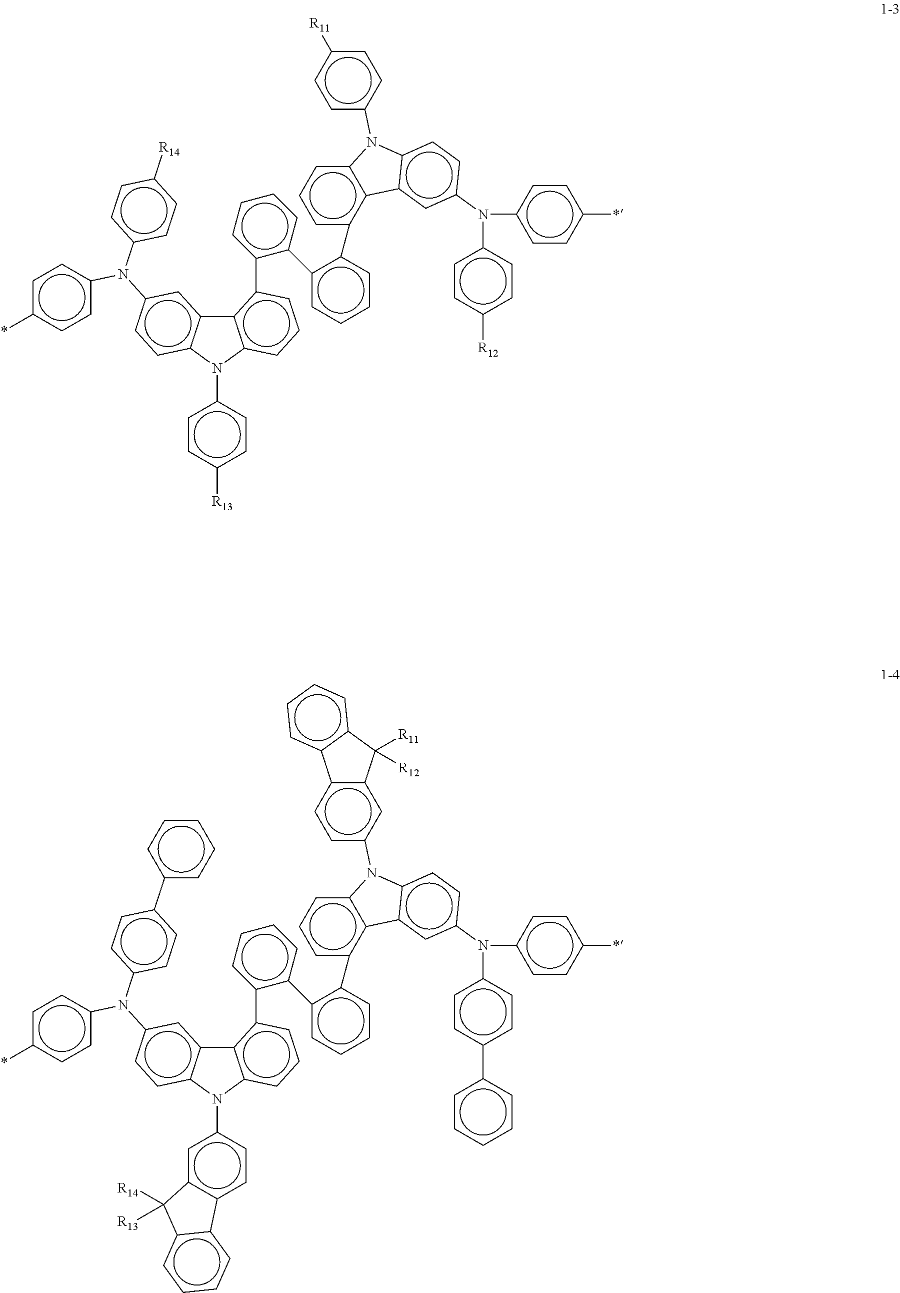 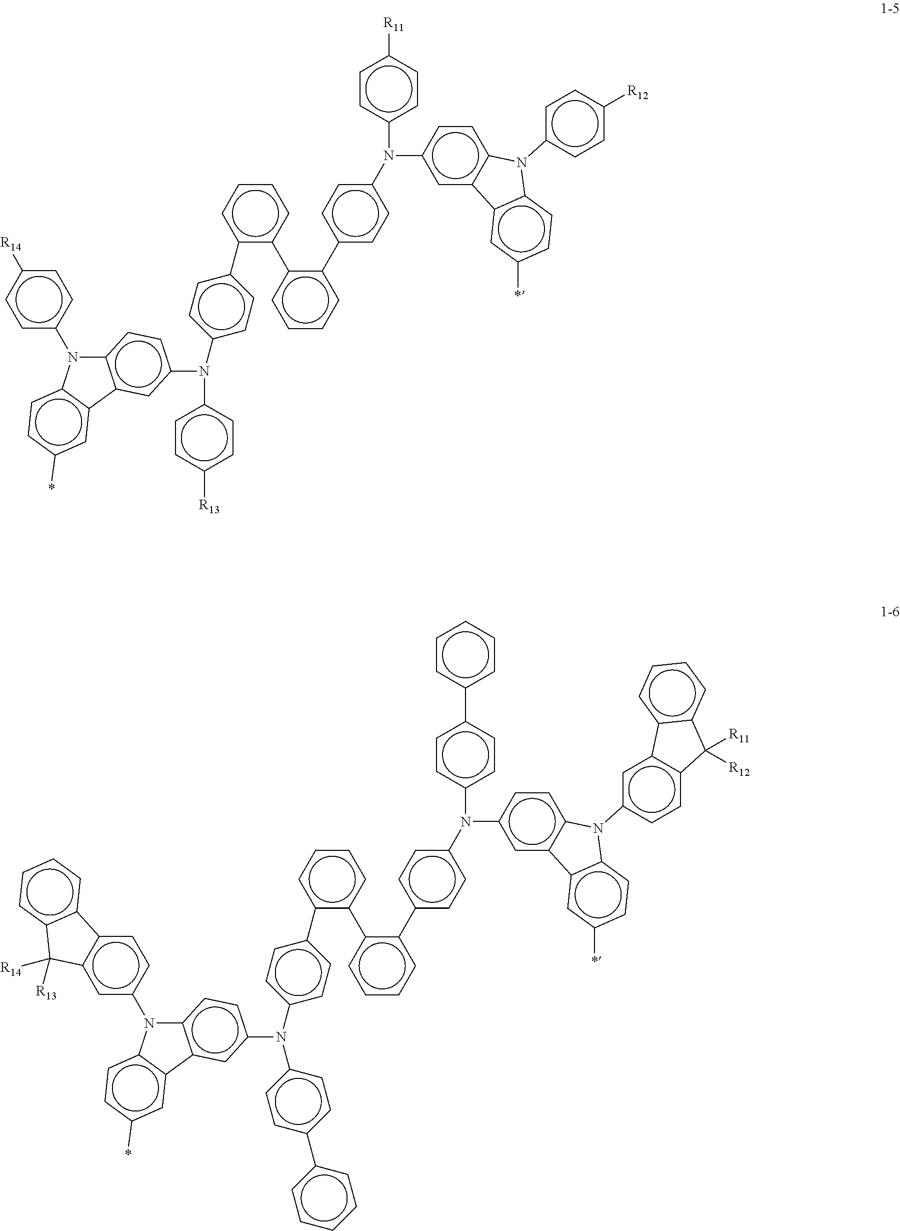 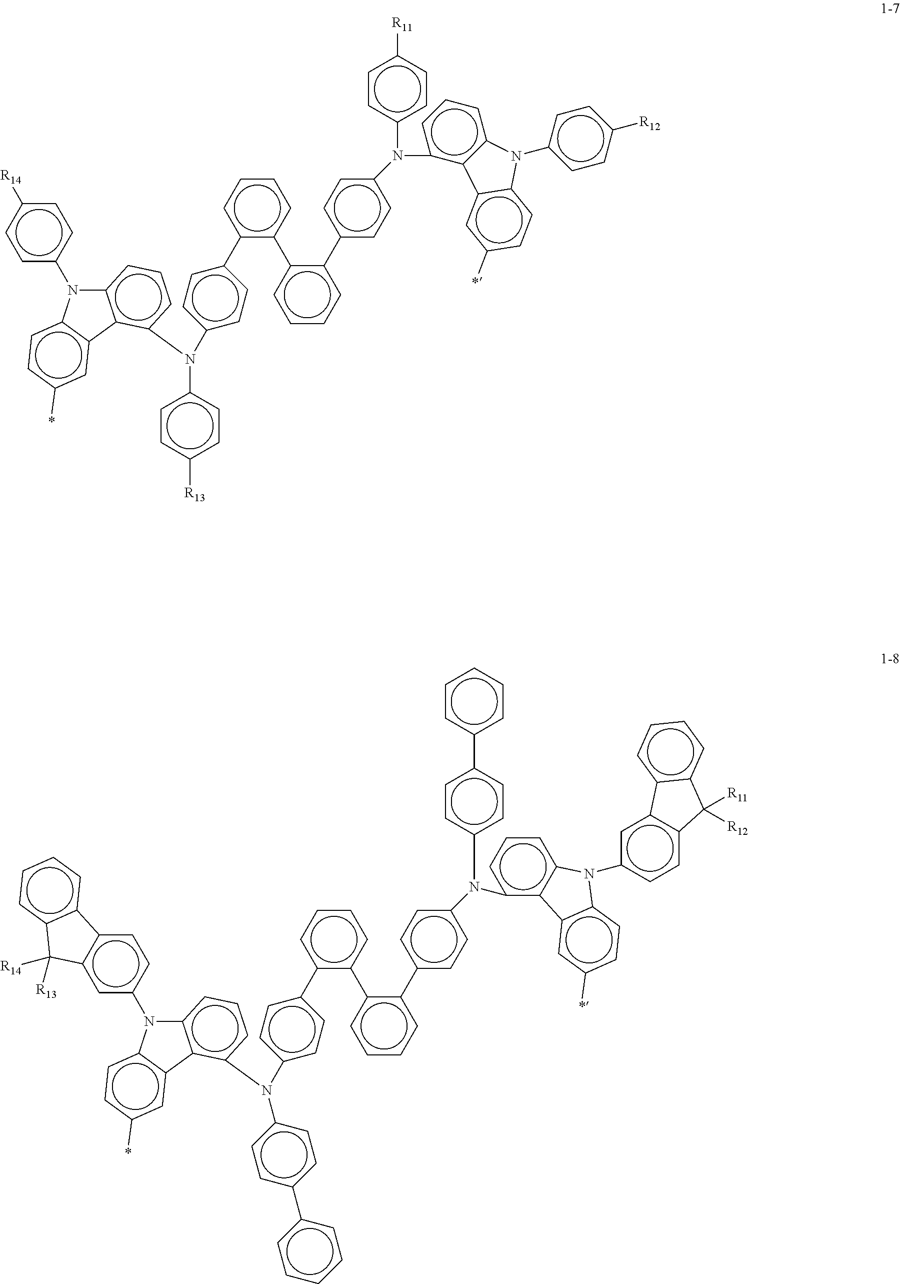 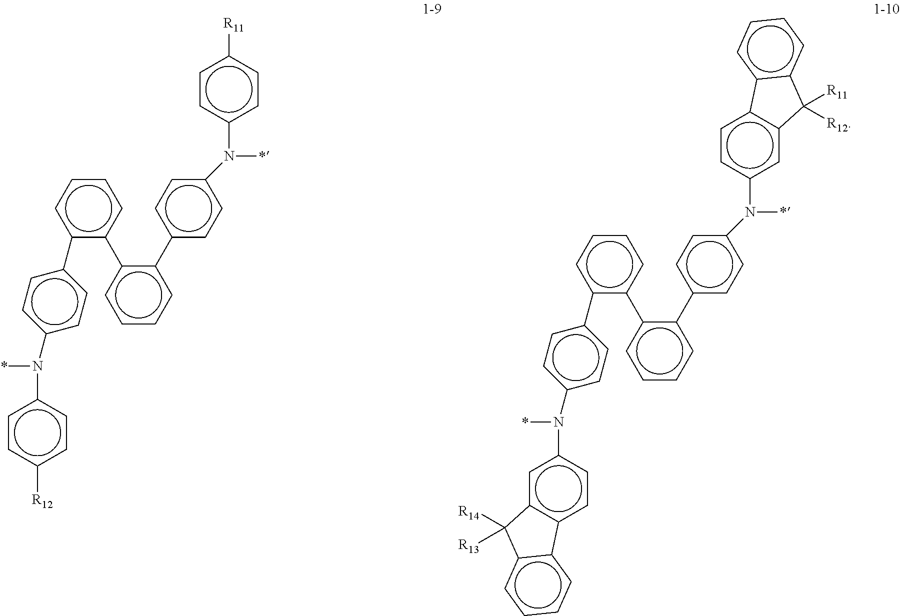
wherein, in Formulae 1-1 to 1-10,
R₁₁ to R₁₄ are each independently hydrogen, deuterium, —F, —Cl, —Br, —I, a hydroxyl group, a cyano group, a nitro group, an amino group, or a C₁-C₆₀ alkyl group, and
* and *′ each indicate a binding site to a neighboring atom.

7. The polymer compound of claim 1, wherein
Q₁ in Formula 3 is a crosslinking group represented by one of Formulae Q-1 to Q-8: 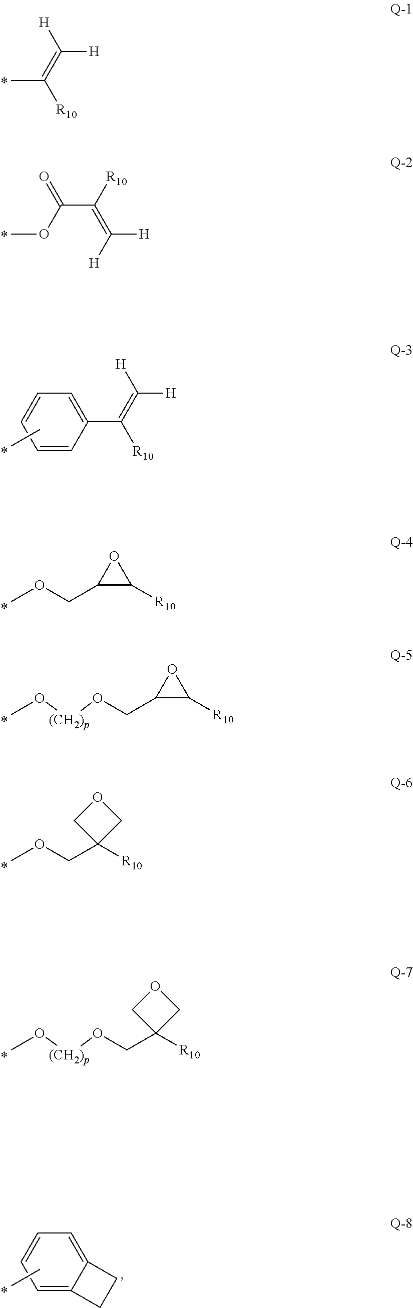
wherein, in Formulae Q-1 to Q-8,
R₁₀ is hydrogen, deuterium, —F, —Cl, —Br, —I, a hydroxyl group, a cyano group, a nitro group, an amino group, or a C₁-C₁₀ alkyl group,
p is an integer from 1 to 10, and
* indicates a binding site to a neighboring atom.

8. The polymer compound of claim 1, wherein
Ar₄ in Formula 3 is a substituent represented by one of Formulae C-1 to C-4: 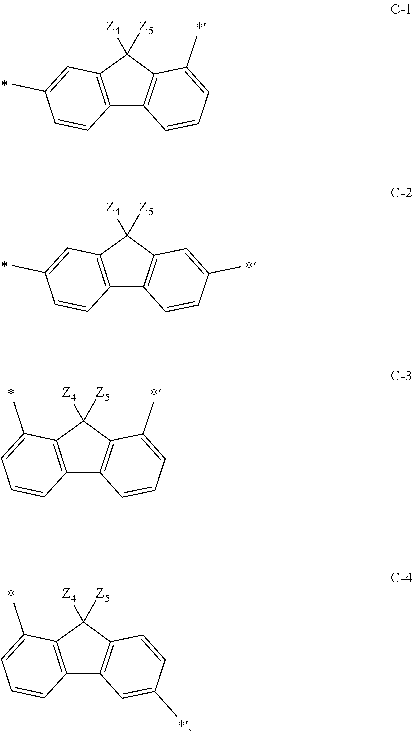
wherein, in Formulae C-1 to C-4,
Z₄ and Z₅ are each independently selected from -(L₁)ₘ₁-(Q₁)ₙ₁, hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-Coo alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group,
at least one of Z₄ and Z₅ is -(L₁)ₘ₁-(Q₁)ₙ₁, and
* and *′ each indicate a binding site to a neighboring atom.

9. The polymer compound of claim 1, wherein
the second repeating unit is represented by Formula 3-1 or 3-2: 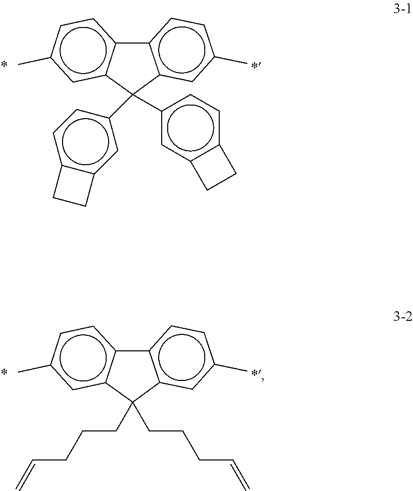
wherein, in Formulae 3-1 and 3-2,
* and *′ each indicate a binding site to a neighboring atom.

10. The polymer compound of claim 1, wherein
an amount of the first repeating unit is in a range of about 35 parts by weight to about 95 parts by weight based on 100 parts by weight of the polymer compound, and
an amount of the second repeating unit is in a range of about 5 parts by weight to about 15 parts by weight based on 100 parts by weight of the polymer compound.

11. The polymer compound of claim 1, further comprising a third repeating unit represented by Formula 4:
Ar₅, Formula 4
wherein, in Formula 4,
Ar₅ is a substituted or unsubstituted C₅-C₃₀ carbocyclic group or a substituted or unsubstituted C₁-C₃₀ heterocyclic group.

12. The polymer compound of claim 1, wherein
the third repeating unit is represented by one of Formulae 4-1 to 4-5: 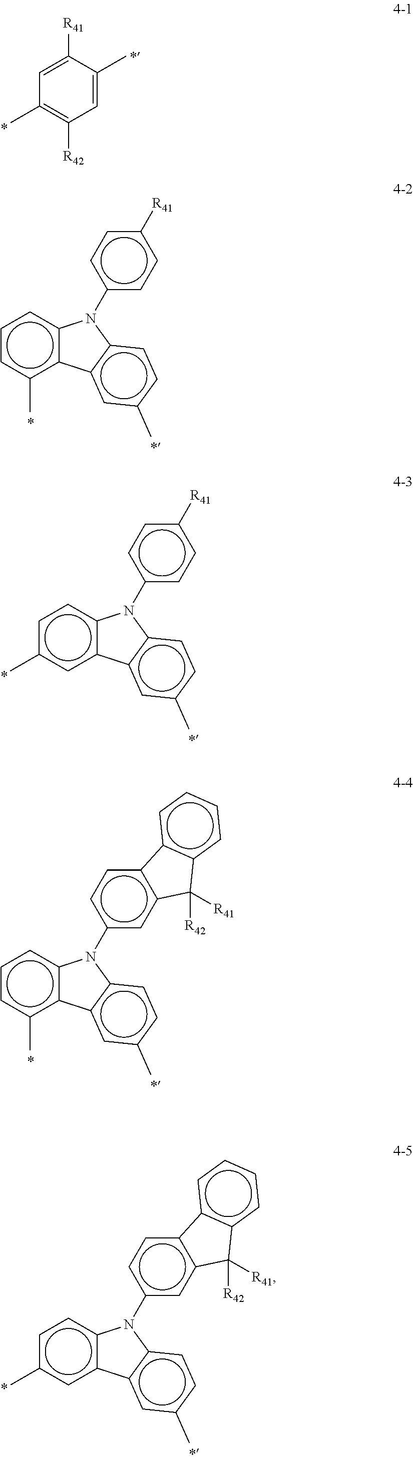
wherein, in Formulae 4-1 to 4-5,
R₄₁ and R₄₂ are each independently hydrogen, deuterium, —F, —Cl, —Br, —I, a hydroxyl group, a cyano group, a nitro group, an amino group, or a C₁-C₆₀ alkyl group, and
* and *′ each indicate a binding site to a neighboring atom.

13. The polymer compound of claim 1, wherein
an amount of the third repeating unit is in a range of about 5 parts by weight to about 50 parts by weight based on 100 parts by weight of the polymer compound.

14. The polymer compound of claim 1, wherein
a number average molecular weight (Mn) of the polymer compound is in a range of about 10,000 Daltons to about 500,000 Daltons.

15. A composition comprising:
the polymer compound of claim 1; and
a liquid medium.

16. The composition of claim 15, further comprising at least one selected from a hole transport material, an electron transport material, and a light-emitting material.

17. The composition of claim 16, wherein
the light-emitting material comprises an organometallic complex compound.

18. An organic light-emitting device comprising:
a first electrode;
a second electrode; and
an organic layer disposed between the first electrode and the second electrode,
wherein the organic layer comprises an emission layer and the polymer compound of claim 1.

19. The organic light-emitting device of claim 18, wherein
the first electrode is an anode,
the second electrode is a cathode,
the organic layer further comprises a hole transport region disposed between the first electrode and the emission layer and an electron transport region disposed between the emission layer and the second electrode,
wherein the hole transport region comprises at least one selected from a hole injection layer, a hole transport layer, a buffer layer, an emission auxiliary layer, and an electron blocking layer,
wherein the electron transport region comprises at least one selected from a hole blocking layer, an electron transport layer, and an electron injection layer, and
wherein a layer comprising the polymer compound is included in the hole transport region.

20. The organic light-emitting device of claim 18, wherein
the emission layer comprises a light-emitting material that emits light from triplet excitons.
